(19) United States
(12) Patent Application Publication
(10) Pub. No.: US 2019/0077901 A1
(43) Pub. Date: Mar. 14, 2019

(54) NOVOLAC-TYPE PHENOLIC HYDROXY GROUP-CONTAINING RESIN, AND RESIST FILM

(71) Applicant: DIC Corporation, Tokyo (JP)

(72) Inventors: Tomoyuki Imada, Ichihara-shi (JP); Yusuke Sato, Ichihara-shi (JP)

(73) Assignee: DIC Corporation, Tokyo (JP)

(21) Appl. No.: 15/743,044

(22) PCT Filed: Jul. 21, 2016
(86) PCT No.: PCT/JP2016/071381

§ 371 Date: Jan. 9, 2018

(30) Foreign Application Priority Data
Aug. 18, 2015 (JP) 2015-161037

(51) Int. Cl. C08G 8/20; C08G 8/14; C08L 61/12; G03F 7/023; G03F 7/11

(52) U.S. Cl. CPC C08G 8/20; C08G 8/14; G03F 7/11; G03F 7/0236; C08L 61/12

(57) ABSTRACT

Provided are a novolac-type phenolic hydroxy group-containing resin having excellent developability, heat resistance, and dry etching resistance and a resist film. The novolac-type phenolic hydroxy group-containing resin includes, as a repeating unit, a structural moiety (I) represented by Structural Formula (1):

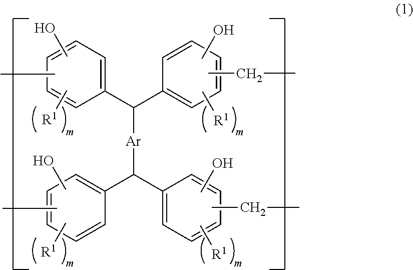

wherein Ar represents an arylene group; R¹'s each independently represent any one of a hydrogen atom, an alkyl group, an alkoxy group, an aryl group, an aralkyl group, and a halogen atom; and m's each independently represent an integer of 1 to 3, or a structural moiety (II) represented by Structural Formula (2):

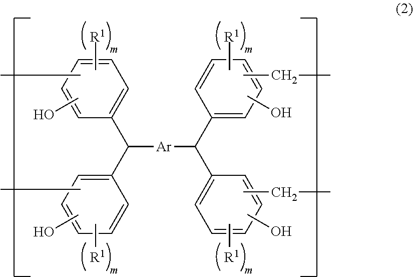

wherein Ar represents an arylene group; R¹'s each independently represent any one of a hydrogen atom, an alkyl group, an alkoxy group, an aryl group, an aralkyl group, and a halogen atom; and m's each independently represent an integer of 1 to 3.

### TECHNICAL FIELD

The present invention relates to a novolac-type phenolic hydroxy group-containing resin having excellent developability, heat resistance, and dry etching resistance and a resist film formed using the same.

### BACKGROUND ART

A phenolic hydroxy group-containing resin is used in an adhesive, a molding material, paint, a photoresist material, an epoxy resin raw material, a curing agent for an epoxy resin, and the like. Since the heat resistance and moisture resistance of the cured product of the phenolic hydroxy group-containing resin are excellent, the resin is also widely used in the electrical and electronic field such as a semiconductor sealing material or an insulating material for a printed wiring board, as a curable composition including the phenolic hydroxy group-containing resin itself as a main agent or as a curing agent of an epoxy resin or the like.

Among these, in the field of a photoresist, a wide variety of resist pattern forming methods subdivided according to the use or the function have been developed one after another. Accordingly, performances required for a resin material for a resist have become more sophisticated and diversified. For example, high developability is required in order to accurately form a fine pattern on a highly-integrated semiconductor with high production efficiency, as well as dry etching resistance and heat resistance in the case of using the resin material in a resist underlayer film. In particular, high heat resistance is required in the case of using the resin material in a resist permanent film.

The phenolic hydroxy group-containing resin most widely used for a photoresist is a cresol novolac-type phenolic hydroxy group-containing resin. However, as described above, this type of resin cannot meet the highly sophisticated and diversified performances currently required in the market, and the heat resistance and developability thereof are also not sufficient (refer to PTL 1).

### CITATION LIST

### Patent Literature

[PTL 1] JP-A-2-55359

### SUMMARY OF INVENTION

### Technical Problem

Therefore, the problem to be solved by the present invention is to provide a novolac-type phenolic hydroxy group-containing resin having excellent developability, heat resistance, and dry etching resistance, and a photosensitive composition, a curable composition, and a resist film each including the same.

### Solution to Problem

The present inventors have conducted extensive research in order to solve the problem, and as a result, they have found that a ladder-like novolac-type phenolic hydroxy group-containing resin obtained by reacting a tetrafunctional phenol compound with formaldehyde has excellent developability, heat resistance, and dry etching resistance, thereby completing the present invention.

That is, the present invention relates to a novolac-type phenolic hydroxy group-containing resin including, as a repeating unit, a structural moiety (I) represented by Structural Formula (1):

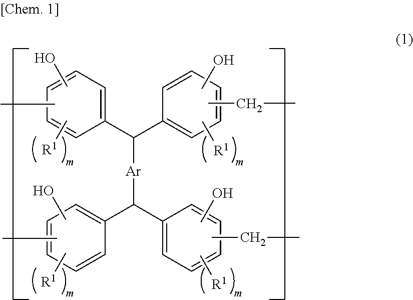

wherein Ar represents an arylene group; R¹'s each independently represent any one of a hydrogen atom, an alkyl group, an alkoxy group, an aryl group, an aralkyl group, and a halogen atom; and m's each independently represent an integer of 1 to 3,

or a structural moiety (II) represented by Structural Formula (2):

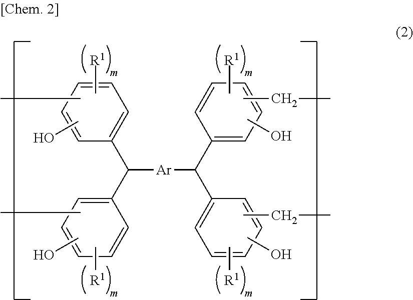

wherein Ar represents an arylene group; R¹'s each independently represent any one of a hydrogen atom, an alkyl group, an alkoxy group, an aryl group, an aralkyl group, and a halogen atom; and m's each independently represent an integer of 1 to 3.

The present invention further relates to a photosensitive composition including the phenolic hydroxy group-containing resin and a photosensitizing agent.

The present invention further relates to a resist film including the photosensitive composition.

The present invention further relates to a curable composition including the phenolic hydroxy group-containing resin and a curing agent.

The present invention further relates to a resist underlayer film including the curable composition.

The present invention further relates to a resist permanent film including the curable composition.

The present invention further relates to a method for producing a novolac-type phenolic hydroxy group-containing resin including reacting a tetrafunctional phenol compound (A) represented by Structural Formula (3) with formaldehyde:

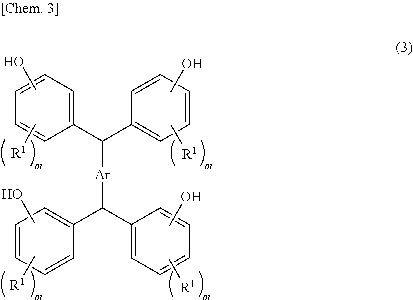

wherein Ar represents an arylene group; R¹'s each independently represent any one of a hydrogen atom, an alkyl group, an alkoxy group, an aryl group, an aralkyl group, and a halogen atom; and m's each independently represent an integer of 1 to 3.

### Advantageous Effects of Invention

According to the present invention, a novolac-type phenolic hydroxy group-containing resin having excellent developability, heat resistance, and dry etching resistance, and a photosensitive composition, a curable composition, and a resist film including the same can be provided.

### BRIEF DESCRIPTION OF DRAWINGS

FIG. 1 is a GPC chart diagram of a tetrafunctional phenol compound (A-1) obtained in Production Example 1.

FIG. 2 is a ¹H-NMR chart diagram of the tetrafunctional phenol compound (A-1) obtained in Production Example 1.

FIG. 3 is a GPC chart diagram of a novolac-type phenolic hydroxy group-containing resin (1) obtained in Example 1.

FIG. 4 is a ¹³C-NMR chart diagram of the novolac-type phenolic hydroxy group-containing resin (1) obtained in Example 1.

FIG. 5 is a TOF-MS chart diagram of the novolac-type phenolic hydroxy group-containing resin (1) obtained in Example 1.

FIG. 6 is a GPC chart diagram of a novolac-type phenolic hydroxy group-containing resin (2) obtained in Example 1.

FIG. 7 is a ¹³C-NMR chart diagram of the novolac-type phenolic hydroxy group-containing resin (2) obtained in Example 1.

FIG. 8 is a TOF-MS chart diagram of the novolac-type phenolic hydroxy group-containing resin (2) obtained in Example 1.

### DESCRIPTION OF EMBODIMENTS

Hereinafter, the present invention will be described in detail.

A novolac-type phenolic hydroxy group-containing resin of the present invention is obtained by reacting a tetrafunctional phenol compound (A) represented by Structural Formula (3) with formaldehyde.

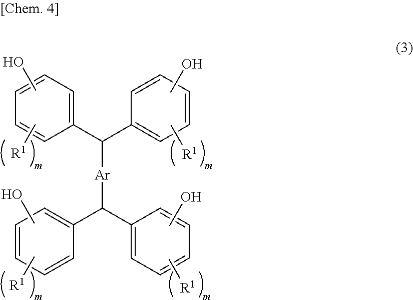

(In the formula, Ar represents an arylene group, R¹'s each independently represent any one of a hydrogen atom, an alkyl group, an alkoxy group, an aryl group, an aralkyl group, and a halogen atom, and m's each independently represent an integer of 1 to 3.)

By using a compound having a unique structure such as the tetrafunctional phenol compound (A) as a raw material of a novolac-type resin, a novolac-type phenolic hydroxy group-containing resin having a so-called ladder-like molecular structure in which the tetrafunctional phenol compounds (A) are knotted with each other by two methylene groups is obtained. Specifically, the ladder-like molecular structure refers to the structure of a novolac-type resin including, as a repeating unit, a structural moiety (I) represented by Structural Formula (1):

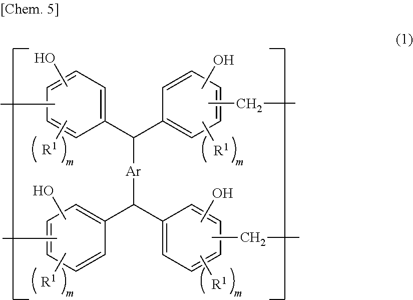

(in the formula, Ar represents an arylene group; R¹'s each independently represent any one of a hydrogen atom, an alkyl group, an alkoxy group, an aryl group, an aralkyl group, and a halogen atom; and m's each independently represent an integer of 1 to 3),

or a structural moiety (II) represented by Structural Formula (2):

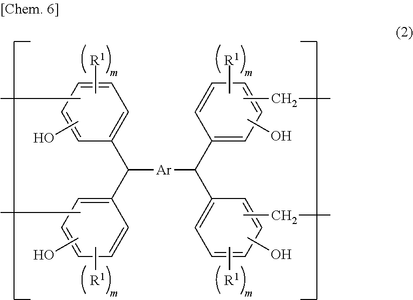

(in the formula, Ar represents an arylene group; R¹'s each independently represent any one of a hydrogen atom, an alkyl group, an alkoxy group, an aryl group, an aralkyl group, and a halogen atom; and m's each independently represent an integer of 1 to 3).

Since the novolac-type phenolic hydroxy group-containing resin of the present invention has the rigid and highly symmetric ladder-like molecular structure, heat resistance and dry etching resistance that are higher than those of conventional resins are realized, and since the novolac-type phenolic hydroxy group-containing resin of the present invention includes phenolic hydroxy groups at a high density, developability thereof is also excellent.

The tetrafunctional phenol compound (A) that constitutes the novolac-type phenolic hydroxy group-containing resin of the present invention has a molecular structure represented by Structural Formula (3).

R¹'s in Structural Formula (3) each independently represent any one of a hydrogen atom, an alkyl group, an alkoxy group, an aryl group, an aralkyl group, and a halogen atom. Examples of the alkyl group include a methyl group, an ethyl group, a propyl group, a butyl group, a pentyl group, a hexyl group, and a cyclohexyl group. Examples of the alkoxy group include a methoxy group, an ethoxy group, a propyloxy group, a butoxy group, a pentyloxy group, a hexyloxy group, and a cyclohexyloxy group. Examples of the aryl group include a phenyl group, a hydroxyphenyl group, a dihydroxyphenyl group, a hydroxyalkoxyphenyl group, an alkoxyphenyl group, a tolyl group, a xylyl group, a naphthyl group, a hydroxynaphthyl group, and a dihydroxynaphthyl group. Examples of the aralkyl group include a phenylmethyl group, a hydroxyphenylmethyl group, a dihydroxyphenylmethyl group, a tolylmethyl group, a xylylmethyl group, a naphthylmethyl group, a hydroxynaphthylmethyl group, a dihydroxynaphthylmethyl group, a phenylethyl group, a hydroxyphenylethyl group, a dihydroxyphenylethyl group, a tolylethyl group, a xylylethyl group, a naphthylethyl group, a hydroxynaphthylethyl group, and a dihydroxynaphthylethyl group. Examples of the halogen atom include a fluorine atom, a chlorine atom, and a bromine atom.

Among these, in view of obtaining the phenolic hydroxy group-containing resin having excellent balance between heat resistance and developability, R¹'s are each preferably an alkyl group, and in view of excellent effect of improving heat resistance by suppression of molecular motion or electron donating properties to an aromatic nucleus and easy industrial availability, R¹'s are each particularly preferably a methyl group.

Furthermore, m's in Structural Formula (1) each independently represent an integer of 1 to 3, and among these, in view of obtaining the phenolic hydroxy group-containing resin having excellent balance between heat resistance and developability, m's are each preferably 1 or 2.

Ar in Structural Formula (1) is an arylene group, and examples thereof include a phenylene group, a naphthylene group, an anthrylene group, and a structural moiety obtained by substituting one or a plurality of hydrogen atoms of these aromatic nuclei with any one of an alkyl group, an alkoxy group, and a halogen atom. Here, the alkyl group, the alkoxy group, and the halogen atom are those enumerated as R¹. Among these, in view of excellent symmetry of the molecular structure and obtaining the novolac-type phenolic hydroxy group-containing resin having excellent developability, heat resistance, and dry etching resistance, Ar is preferably a phenylene group.

Specific examples of the tetrafunctional phenol compound (A) represented by Structural Formula (3) include a compound having a molecular structure represented by any one of Structural Formulas (3-1) to (3-45).

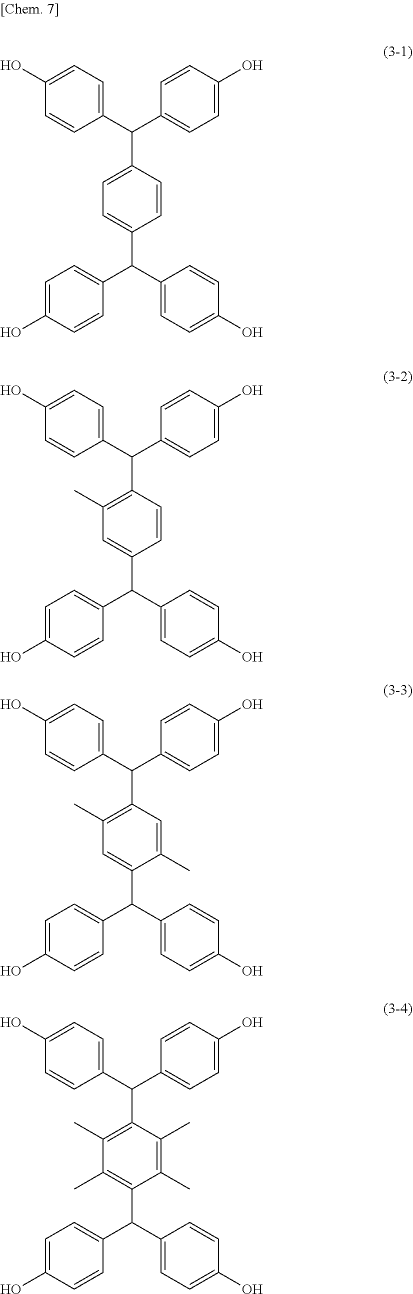 [SMILES: Oc1ccc(C(c2ccc(O)cc2)c2ccc(C(c3ccc(O)cc3)c3ccc(O)cc3)cc2)cc1 ; Cc1cc(C(c2ccc(O)cc2)c2ccc(O)cc2)ccc1C(c1ccc(O)cc1)c1ccc(O)cc1 ; Cc1cc(C(c2ccc(O)cc2)c2ccc(O)cc2)c(C)cc1C(c1ccc(O)cc1)c1ccc(O)cc1 ; Cc1c(C)c(C(c2ccc(O)cc2)c2ccc(O)cc2)c(C)c(C)c1C(c1ccc(O)cc1)c1ccc(O)cc1]

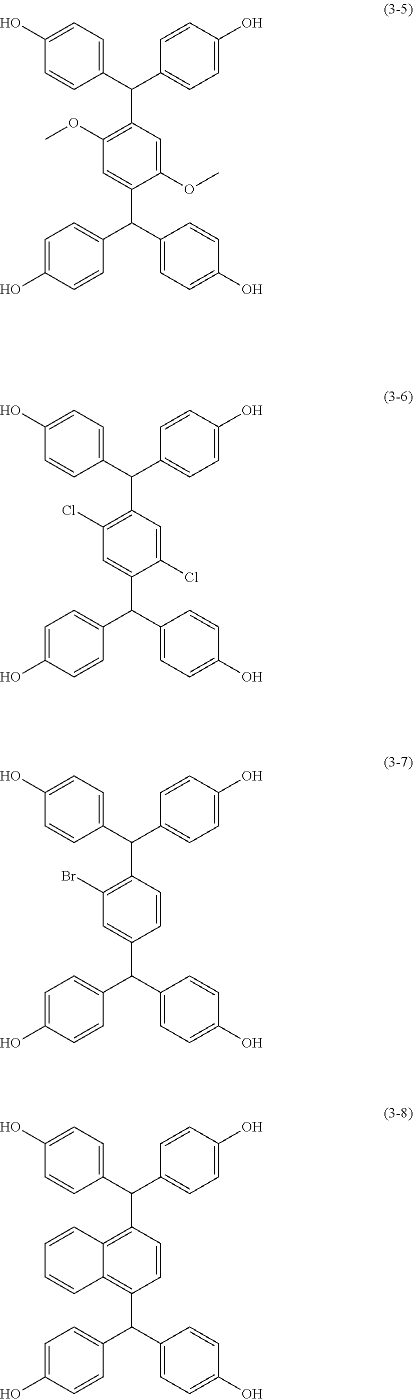 [SMILES: COc1cc(C(c2ccc(O)cc2)c2ccc(O)cc2)c(OC)cc1C(c1ccc(O)cc1)c1ccc(O)cc1 ; Oc1ccc(C(c2ccc(O)cc2)c2cc(Cl)c(C(c3ccc(O)cc3)c3ccc(O)cc3)cc2Cl)cc1 ; Oc1ccc(C(c2ccc(O)cc2)c2ccc(C(c3ccc(O)cc3)c3ccc(O)cc3)c(Br)c2)cc1 ; Oc1ccc(C(c2ccc(O)cc2)c2ccc(C(c3ccc(O)cc3)c3ccc(O)cc3)c3ccccc23)cc1]

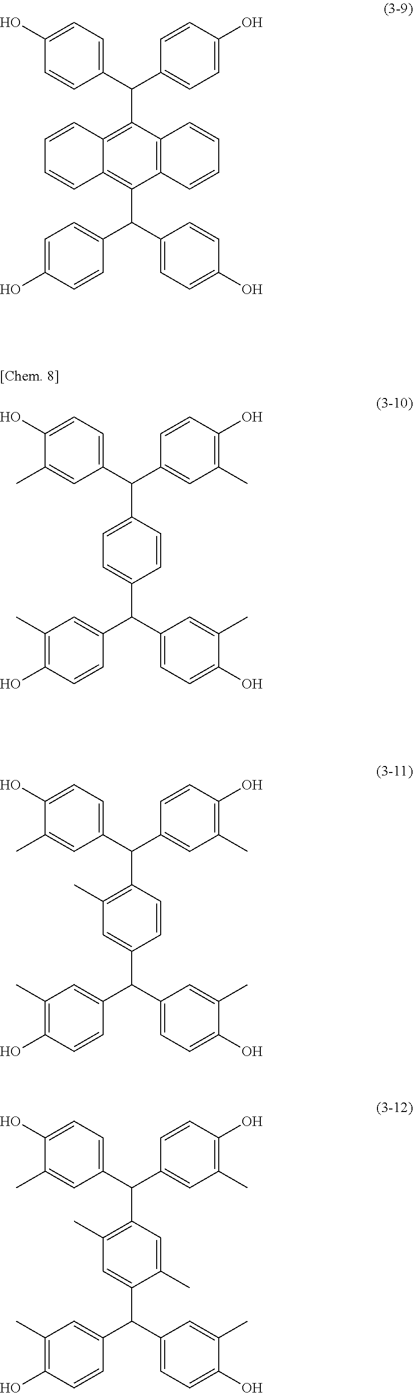 [SMILES: Oc1ccc(C(c2ccc(O)cc2)c2c3ccccc3c(C(c3ccc(O)cc3)c3ccc(O)cc3)c3ccccc23)cc1 ; Cc1cc(C(c2ccc(C(c3ccc(O)c(C)c3)c3ccc(O)c(C)c3)cc2)c2ccc(O)c(C)c2)ccc1O ; Cc1cc(C(c2ccc(O)c(C)c2)c2ccc(C(c3ccc(O)c(C)c3)c3ccc(O)c(C)c3)c(C)c2)ccc1O ; Cc1cc(C(c2ccc(O)c(C)c2)c2cc(C)c(C(c3ccc(O)c(C)c3)c3ccc(O)c(C)c3)cc2C)ccc1O]

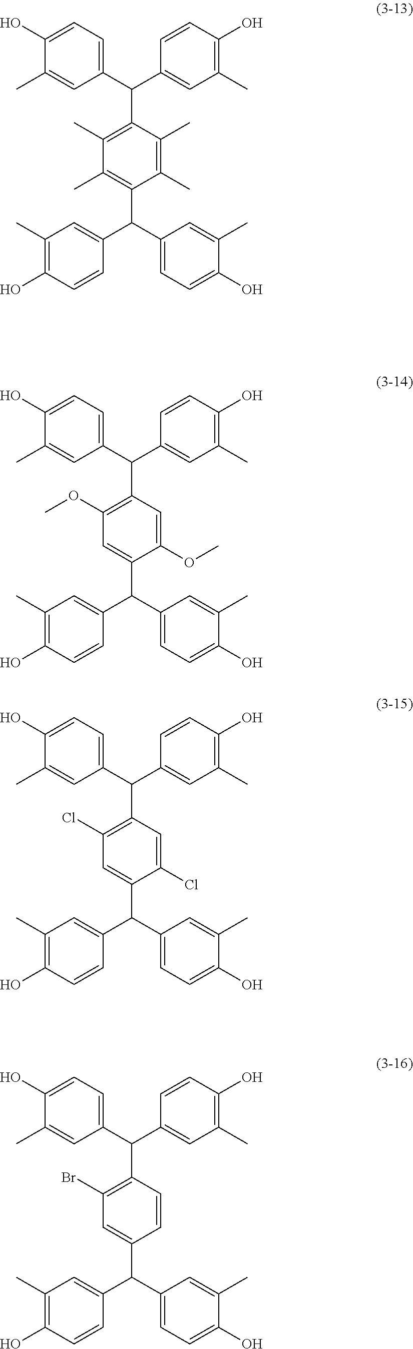 [SMILES: Cc1cc(C(c2ccc(O)c(C)c2)c2c(C)c(C)c(C(c3ccc(O)c(C)c3)c3ccc(O)c(C)c3)c(C)c2C)ccc1O ; COc1cc(C(c2ccc(O)c(C)c2)c2ccc(O)c(C)c2)c(OC)cc1C(c1ccc(O)c(C)c1)c1ccc(O)c(C)c1 ; Cc1cc(C(c2ccc(O)c(C)c2)c2cc(Cl)c(C(c3ccc(O)c(C)c3)c3ccc(O)c(C)c3)cc2Cl)ccc1O ; Cc1cc(C(c2ccc(O)c(C)c2)c2ccc(C(c3ccc(O)c(C)c3)c3ccc(O)c(C)c3)c(Br)c2)ccc1O]

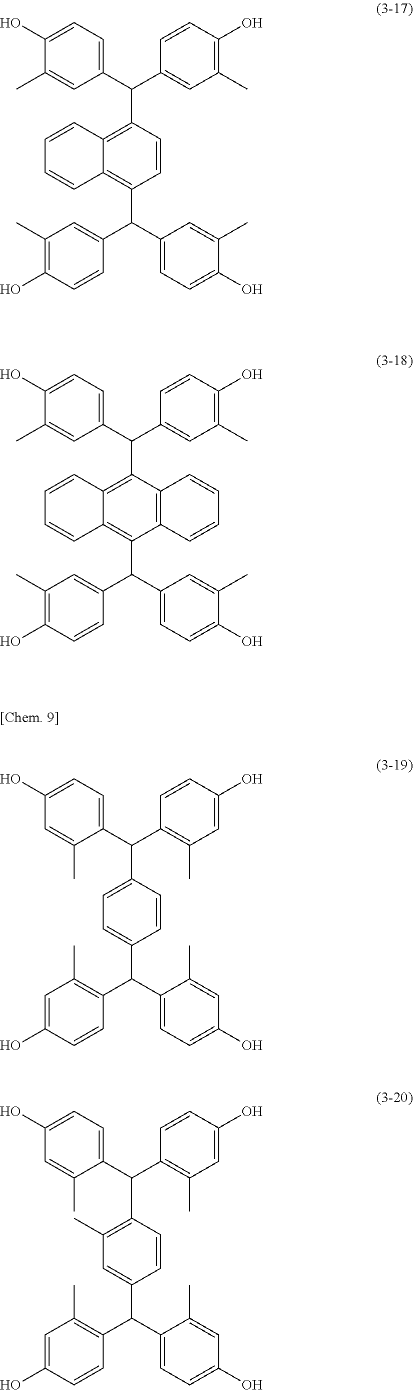 [SMILES: Cc1cc(C(c2ccc(O)c(C)c2)c2ccc(C(c3ccc(O)c(C)c3)c3ccc(O)c(C)c3)c3ccccc23)ccc1O ; Cc1cc(C(c2ccc(O)c(C)c2)c2c3ccccc3c(C(c3ccc(O)c(C)c3)c3ccc(O)c(C)c3)c3ccccc23)ccc1O ; Cc1cc(O)ccc1C(c1ccc(C(c2ccc(O)cc2C)c2ccc(O)cc2C)cc1)c1ccc(O)cc1C ; Cc1cc(O)ccc1C(c1ccc(C(c2ccc(O)cc2C)c2ccc(O)cc2C)c(C)c1)c1ccc(O)cc1C]

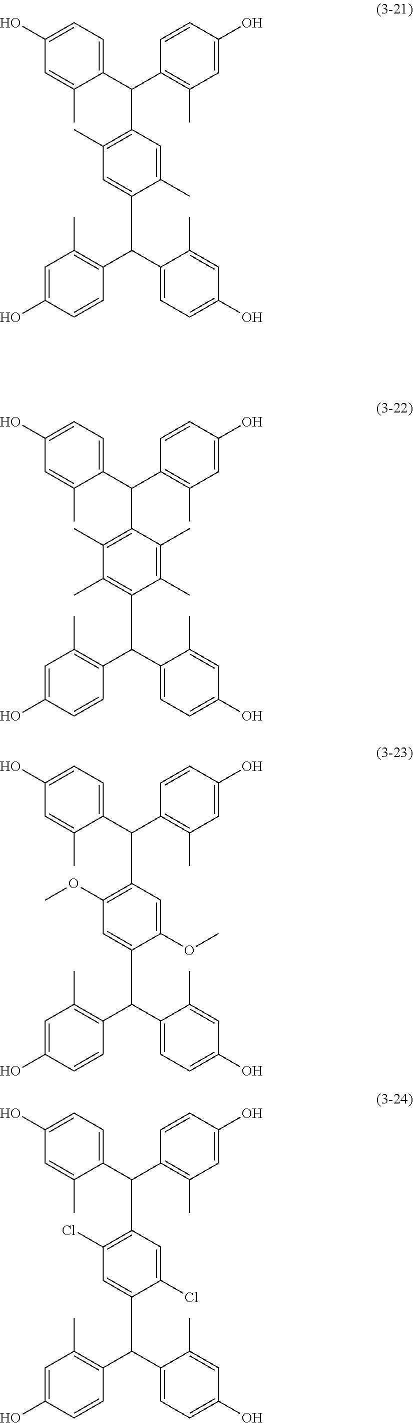

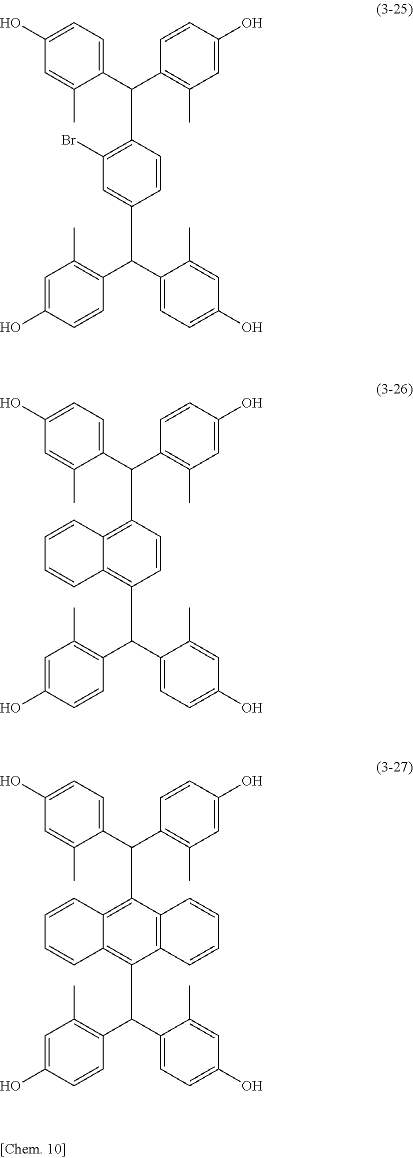 [SMILES: Cc1cc(O)ccc1C(c1ccc(C(c2ccc(O)cc2C)c2ccc(O)cc2C)c(Br)c1)c1ccc(O)cc1C ; Cc1cc(O)ccc1C(c1ccc(O)cc1C)c1ccc(C(c2ccc(O)cc2C)c2ccc(O)cc2C)c2ccccc12 ; Cc1cc(O)ccc1C(c1ccc(O)cc1C)c1c2ccccc2c(C(c2ccc(O)cc2C)c2ccc(O)cc2C)c2ccccc12]

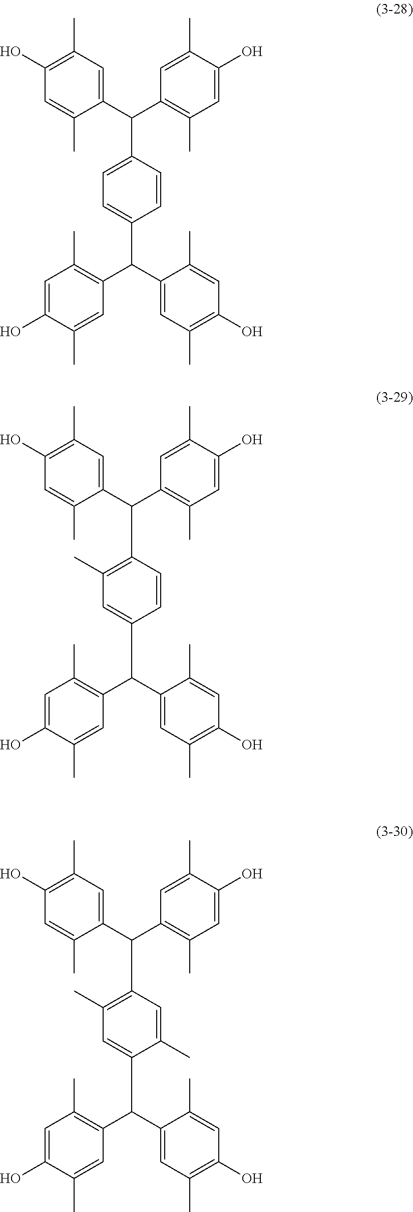

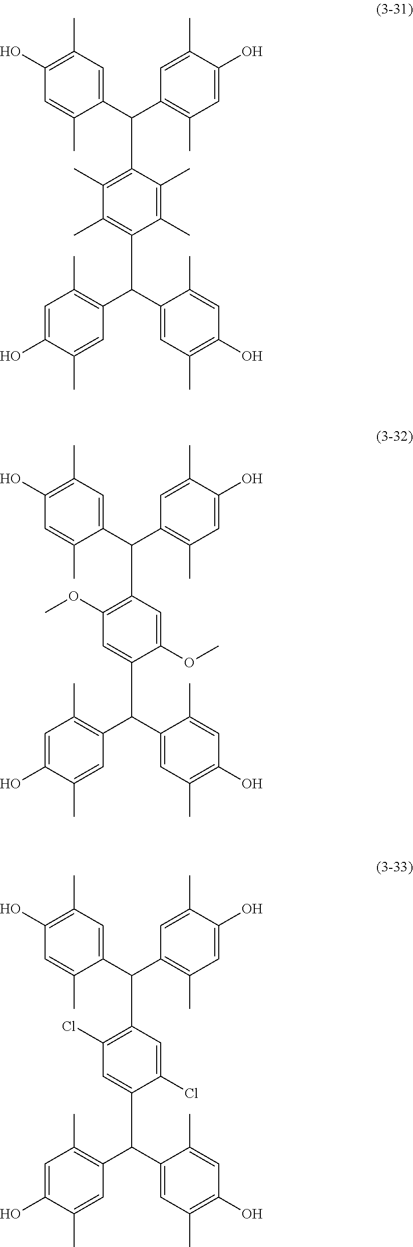 [SMILES: Cc1cc(C(c2cc(C)c(O)cc2C)c2c(C)c(C)c(C(c3cc(C)c(O)cc3C)c3cc(C)c(O)cc3C)c(C)c2C)c(C)cc1O ; COc1cc(C(c2cc(C)c(O)cc2C)c2cc(C)c(O)cc2C)c(OC)cc1C(c1cc(C)c(O)cc1C)c1cc(C)c(O)cc1C ; Cc1cc(C(c2cc(C)c(O)cc2C)c2cc(Cl)c(C(c3cc(C)c(O)cc3C)c3cc(C)c(O)cc3C)cc2Cl)c(C)cc1O]

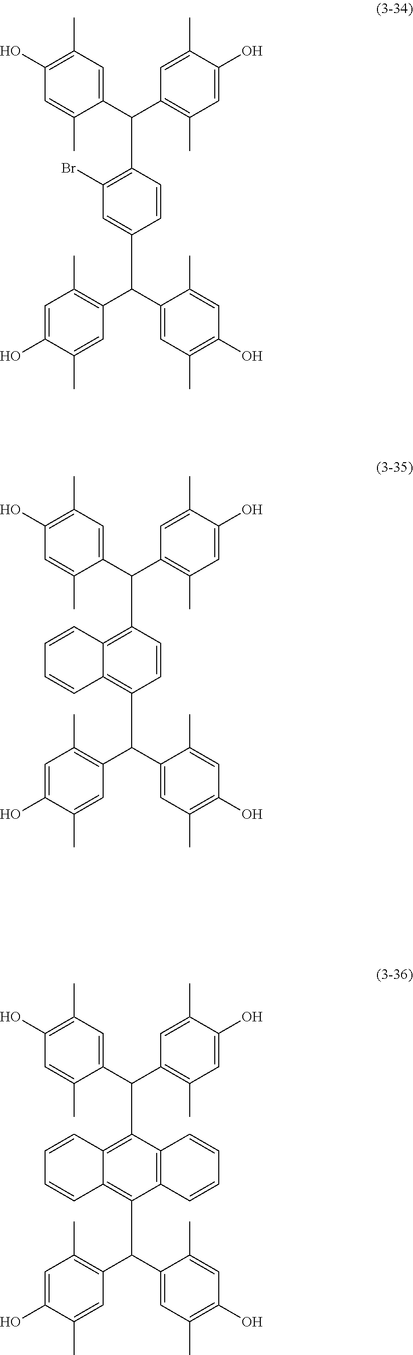 [SMILES: Cc1cc(C(c2ccc(C(c3cc(C)c(O)cc3C)c3cc(C)c(O)cc3C)c(Br)c2)c2cc(C)c(O)cc2C)c(C)cc1O ; Cc1cc(C(c2cc(C)c(O)cc2C)c2ccc(C(c3cc(C)c(O)cc3C)c3cc(C)c(O)cc3C)c3ccccc23)c(C)cc1O ; Cc1cc(C(c2cc(C)c(O)cc2C)c2c3ccccc3c(C(c3cc(C)c(O)cc3C)c3cc(C)c(O)cc3C)c3ccccc23)c(C)cc1O]

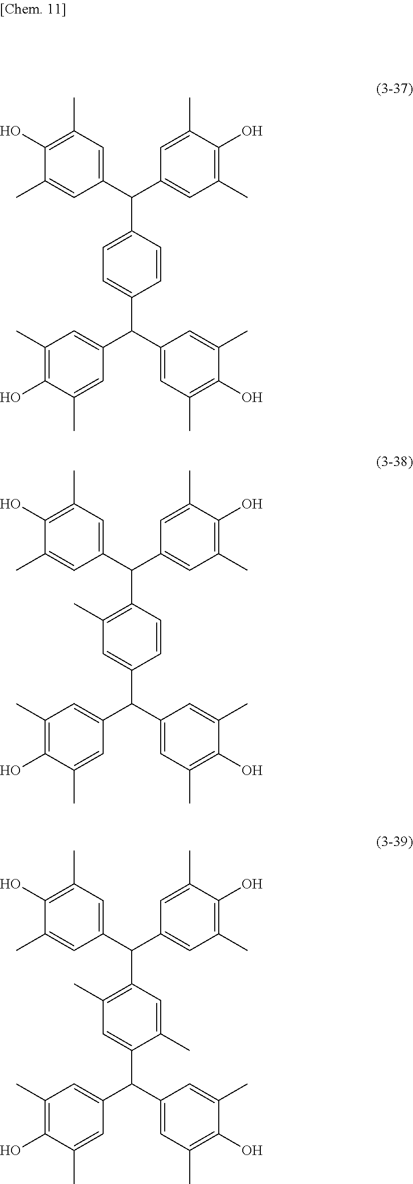

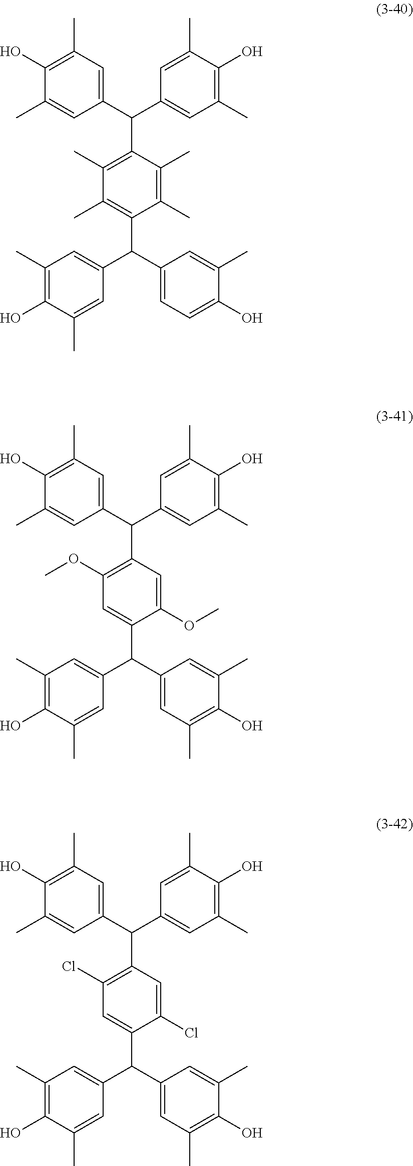 [SMILES: Cc1cc(C(c2cc(C)c(O)c(C)c2)c2c(C)c(C)c(C(c3cc(C)c(O)c(C)c3)c3cc(C)c(O)c(C)c3)c(C)c2C)ccc1O ; COc1cc(C(c2cc(C)c(O)c(C)c2)c2cc(C)c(O)c(C)c2)c(OC)cc1C(c1cc(C)c(O)c(C)c1)c1cc(C)c(O)c(C)c1 ; Cc1cc(C(c2cc(C)c(O)c(C)c2)c2cc(Cl)c(C(c3cc(C)c(O)c(C)c3)c3cc(C)c(O)c(C)c3)cc2Cl)cc(C)c1O]

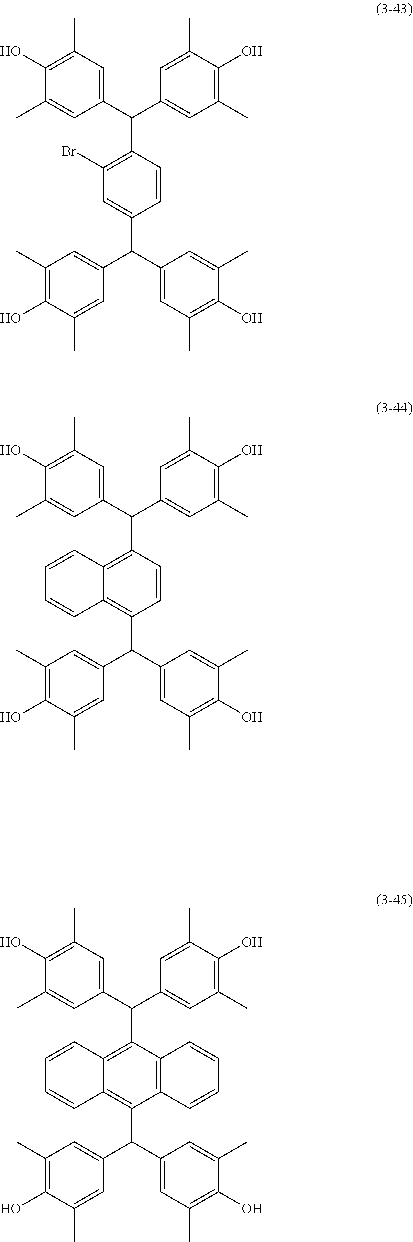 [SMILES: Cc1cc(C(c2cc(C)c(O)c(C)c2)c2ccc(C(c3cc(C)c(O)c(C)c3)c3cc(C)c(O)c(C)c3)c(Br)c2)cc(C)c1O ; Cc1cc(C(c2cc(C)c(O)c(C)c2)c2ccc(C(c3cc(C)c(O)c(C)c3)c3cc(C)c(O)c(C)c3)c3ccccc23)cc(C)c1O ; Cc1cc(C(c2cc(C)c(O)c(C)c2)c2c3ccccc3c(C(c3cc(C)c(O)c(C)c3)c3cc(C)c(O)c(C)c3)c3ccccc23)cc(C)c1O]

The tetrafunctional phenol compound (A) can be obtained by, for example, a method of reacting a phenol compound (a1) and an aromatic dialdehyde (a2) in the presence of an acid catalyst.

The phenol compound (a1) is a compound obtained by substituting a part or all of the hydrogen atoms bonded to the aromatic ring of the phenol with any one of an alkyl group, an alkoxy group, an aryl group, an aralkyl group, and a halogen atom. Examples of the alkyl group include a methyl group, an ethyl group, a propyl group, a butyl group, a pentyl group, a hexyl group, and a cyclohexyl group. Examples of the alkoxy group include a methoxy group, an ethoxy group, a propyloxy group, a butoxy group, a pentyloxy group, a hexyloxy group, and a cyclohexyloxy group. Examples of the aryl group include a phenyl group, a hydroxyphenyl group, a dihydroxyphenyl group, a hydroxyalkoxyphenyl group, an alkoxyphenyl group, a tolyl group, a xylyl group, a naphthyl group, a hydroxynaphthyl group, and a dihydroxynaphthyl group. Examples of the aralkyl group include a phenylmethyl group, a hydroxyphenylmethyl group, a dihydroxyphenylmethyl group, a tolylmethyl group, a xylylmethyl group, a naphthylmethyl group, a hydroxynaphthylmethyl group, a dihydroxynaphthylmethyl group, a phenylethyl group, a hydroxyphenylethyl group, a dihydroxyphenylethyl group, a tolylethyl group, a xylylethyl group, a naphthylethyl group, a hydroxynaphthylethyl group, and a dihydroxynaphthylethyl group. Examples of the halogen atom include a fluorine atom, a chlorine atom, and a bromine atom. The phenol compound may be used singly, or two or more kinds thereof may be used in combination.

Among these, in view of obtaining a novolac-type phenolic hydroxy group-containing resin having excellent developability, heat resistance, and dry etching resistance, an alkyl-substituted phenol is preferable, and specific examples thereof include o-cresol, m-cresol, p-cresol, 2,5-xylenol, 3,5-xylenol, 3,4-xylenol, 2,4-xylenol, 2,6-xylenol, 2,3,5-trimethylphenol, and 2,3,6-trimethylphenol. Among these, 2,5-xylenol and 2,6-xylenol are particularly preferable.

The aromatic dialdehyde (a2) may be any compound as long as it is a compound obtained by substituting two of the hydrogen atoms bonded to the aromatic ring of an aromatic compound such as benzene, naphthalene, anthracene and a derivative thereof with formyl groups. Among these, in view of excellent symmetry of the molecular structure and obtaining the novolac-type phenolic hydroxy group-containing resin having excellent developability, heat resistance, and dry etching resistance, it is preferable that the compound has a structure in which the two formyl groups are bonded to the aromatic ring at para positions to each other. Examples of such compound include a phenylene-type dialdehyde compound such as terephthalaldehyde, 2-methylterephthalaldehyde, 2,5-dimethylterephthalaldehyde, 2,3,5,6-tetramethylbenzene-1,4-dicarbaldehyde, 2,5-dimethoxyterephthalaldehyde, 2,5-dichloroterephthalaldehyde, and 2-bromoterephthalaldehyde; a naphthylene-type dialdehyde compound such as 1,4-naphthalenedicarbaldehyde; and an anthrylene-type dialdehyde compound such as 9,10-anthracenedicarbaldehyde. Each of these compounds may be used singly, or two or more kinds thereof may be used in combination.

Among these aromatic dialdehydes (a2), in view of excellent symmetry of the molecular structure and obtaining the novolac-type phenolic hydroxy group-containing resin having excellent developability, heat resistance, and dry etching resistance, a phenylene-type dialdehyde compound is preferable.

The reaction molar ratio between the phenol compound (a1) and the aromatic dialdehyde (a2) [(a1)/(a2)] is preferably 1/0.1 to 1/0.25, in view of obtaining the desired tetrafunctional phenol compound (A) at a high yield and high purity.

Examples of the acid catalyst used in the reaction between the phenol compound (a1) and the aromatic dialdehyde (a2) include acetic acid, oxalic acid, sulfuric acid, hydrochloric acid, phenolsulfonic acid, p-toluenesulfonic acid, zinc acetate, and manganese acetate. Each of these acid catalysts may be used singly, or two or more kinds thereof may be used in combination. Among these, from the viewpoint of excellent catalytic activity, sulfuric acid and p-toluenesulfonic acid are preferable.

The reaction between the phenol compound (a1) and the aromatic dialdehyde (a2) may be carried out in an organic solvent as necessary. Examples of the solvent used here include a monoalcohol such as methanol, ethanol, and propanol; a polyol such as ethylene glycol, 1,2-propanediol, 1,3-propanediol, 1,4-butanediol, 1,5-pentanediol, 1,6-hexanediol, 1,7-heptanediol, 1,8-octanediol, 1,9-nonanediol, trimethylene glycol, diethylene glycol, polyethylene glycol, and glycerin; a glycol ether such as 2-ethoxyethanol, ethylene glycol monomethyl ether, ethylene glycol monoethyl ether, ethylene glycol monopropyl ether, ethylene glycol monobutyl ether, ethylene glycol monopentyl ether, ethylene glycol dimethyl ether, ethylene glycol ethyl methyl ether, and ethylene glycol monophenyl ether; a cyclic ether such as 1,3-dioxane, 1,4-dioxane, and tetrahydrofuran; a glycol ester such as ethylene glycol acetate; a ketone such as acetone, methyl ethyl ketone, and methyl isobutyl ketone, and an aromatic hydrocarbon such as benzene, toluene, and xylene. Each of these solvents may be used singly, or two or more kinds thereof may be used together as a mixed solvent. Among these, in view of excellent solubility of the obtained tetrafunctional phenol compound (A), 2-ethoxyethanol is preferable.

The reaction between the phenol compound (a1) and the aromatic dialdehyde (a2) may be carried out, for example, at 60° C. to 140° C. for 0.5 to 100 hours.

After the end of the reaction, the unreacted phenol compound (a1) or the aromatic dialdehyde (a2) and the acid catalyst used are removed from the reaction product, for example, by the method in which the reaction product is put into a poor solvent (S1) for the tetrafunctional phenol compound (A), a precipitate is isolated by filtration, and then the obtained precipitate is redissolved in a solvent (S2) of which solubility for the tetrafunctional phenol compound (A) is high and which is miscible with the poor solvent (S1), so as to obtain the purified tetrafunctional phenol compound (A).

In view of obtaining the phenolic hydroxy group-containing resin having both excellent developability and excellent heat resistance, the purity of the tetrafunctional phenol compound (A) calculated from the GPC chart diagram is preferably 90% or higher, more preferably 94% or higher, and particularly preferably 98% or higher. The purity of the tetrafunctional phenol compound (A) can be obtained from the area ratio of the gel permeation chromatography (GPC) chart diagram.

The measurement condition for GPC in the present invention is as follows.

### [Measurement Condition for GPC]

Measurement device: “HLC-8220 GPC” manufactured by Tosoh Corporation

Column: “Shodex KF802” (8.0 mmϕ×300 mm) manufactured by Showa Denko K.K.

+“Shodex KF802” (8.0 mmϕ×300 mm) manufactured by Showa Denko K.K.

+“Shodex KF803” (8.0 mmϕ×300 mm) manufactured by Showa Denko K.K.

+“Shodex KF804” (8.0 mmϕ×300 mm) manufactured by Showa Denko K.K.

Column temperature: 40° C.

Detector: RI (differential refractometer)

Data processing: “GPC-8020 MODEL II VERSION 4.30” manufactured by Tosoh Corporation

Eluent: tetrahydrofuran

Flow rate: 1.0 ml/min

Sample: a sample obtained by filtering 0.5% by mass (in terms of a resin solid content) of tetrahydrofuran solution through a microfilter

Injection volume: 0.1 ml

Standard sample: the following monodisperse polystyrene

(Standard sample: monodisperse polystyrene)

“A-500” manufactured by Tosoh Corporation

“A-2500” manufactured by Tosoh Corporation

“A-5000” manufactured by Tosoh Corporation

“F-1” manufactured by Tosoh Corporation

“F-2” manufactured by Tosoh Corporation

“F-4” manufactured by Tosoh Corporation

“F-10” manufactured by Tosoh Corporation

“F-20” manufactured by Tosoh Corporation

Examples of the poor solvent (S1) used for the purification of the tetrafunctional phenol compound (A) include water; a monoalcohol such as methanol, ethanol, propanol, and ethoxyethanol; an aliphatic hydrocarbon such as n-hexane, n-heptane, n-octane, and cyclohexane; and an aromatic hydrocarbon such as toluene and xylene. These solvents may be used singly, or two or more kinds thereof may be used in combination. Among these, in view of excellent solubility of the acid catalyst, water, methanol, and ethoxyethanol are preferable.

Examples of the solvent (S2) include a monoalcohol such as methanol, ethanol, and propanol; a polyol such as ethylene glycol, 1,2-propanediol, 1,3-propanediol, 1,4-butanediol, 1,5-pentanediol, 1,6-hexanediol, 1,7-heptanediol, 1,8-octanediol, 1,9-nonanediol, trimethylene glycol, diethylene glycol, polyethylene glycol, and glycerin; a glycol ether such as 2-ethoxyethanol, ethylene glycol monomethyl ether, ethylene glycol monoethyl ether, ethylene glycol monopropyl ether, ethylene glycol monobutyl ether, ethylene glycol monopentyl ether, ethylene glycol dimethyl ether, ethylene glycol ethyl methyl ether, and ethylene glycol monophenyl ether; a cyclic ether such as 1,3-dioxane and 1,4-dioxane; a glycol ester such as ethylene glycol acetate; and a ketone such as acetone, methyl ethyl ketone, and methyl isobutyl ketone. Each of these solvents may be used singly, or two or more kinds thereof may be used in combination. Among these, in the case where water or a monoalcohol is used as the poor solvent (S1), it is preferable that acetone is used as the solvent (S2).

As described above, the novolac-type phenolic hydroxy group-containing resin of the present invention is obtained by reacting the tetrafunctional phenol compound (A) with formaldehyde. The formaldehyde that is used in the reaction may be formaldehyde in any state, such as formalin that is in the state of an aqueous solution or paraformaldehyde that is in the state of a solid.

In view of the ability to inhibit the resin from having excessively high molecular weight (gelation) and obtaining the novolac-type phenolic hydroxy group-containing resin having suitable molecular weight as a resist material, the reaction ratio of the formaldehyde to the tetrafunctional phenol compound (A) is set such that the number of moles of an aldehyde compound (C) is preferably 0.5 to 7.0 mol and more preferably 0.6 to 6.0 mol with respect to 1 mol of the tetrafunctional phenol compound (A).

The reaction between the tetrafunctional phenol compound (A) and formaldehyde is carried out under a conventional acid catalyst condition, as in the general method for producing a novolac resin. Examples of the acid catalyst used here include acetic acid, oxalic acid, sulfuric acid, hydrochloric acid, phenolsulfonic acid, p-toluenesulfonic acid, zinc acetate, and manganese acetate. Each of these acid catalysts may be used singly, and two or more kinds thereof may be used in combination. Among these, from the viewpoint of excellent catalytic activity, sulfuric acid and p-toluenesulfonic acid are preferable.

The reaction between the tetrafunctional phenol compound (A) and formaldehyde may be carried out in an organic solvent as necessary. Examples of the solvent used here include a monoalcohol such as methanol, ethanol, and propanol; a monocarboxylic acid such as acetic acid, propionic acid, butyric acid, pentanoic acid, and hexanoic acid; a polyol such as ethylene glycol, 1,2-propanediol, 1,3-propanediol, 1,4-butanediol, 1,5-pentanediol, 1,6-hexanediol, 1,7-heptanediol, 1,8-octanediol, 1,9-nonanediol, trimethylene glycol, diethylene glycol, polyethylene glycol, and glycerin; a glycol ether such as 2-ethoxyethanol, ethylene glycol monomethyl ether, ethylene glycol monoethyl ether, ethylene glycol monopropyl ether, ethylene glycol monobutyl ether, ethylene glycol monopentyl ether, ethylene glycol dimethyl ether, ethylene glycol ethyl methyl ether, and ethylene glycol monophenyl ether; a cyclic ether such as 1,3-dioxane, 1,4-dioxane, and tetrahydrofuran; a glycol ester such as ethylene glycol acetate; and a ketone such as acetone, methyl ethyl ketone, and methyl isobutyl ketone. Each of these solvents may be used singly, or two or more kinds thereof may be used together as a mixed solvent. Among these, in view of excellent solubility of the obtained novolac-type phenolic hydroxy group-containing resin, a mixed solvent of a monoalcohol such as methanol and a monocarboxylic acid such as acetic acid is preferable.

The reaction between the tetrafunctional phenol compound (A) and formaldehyde is carried out, for example, at 60° C. to 140° C. for 0.5 to 100 hours. After the end of the reaction, an operation such as a reprecipitation operation which is performed by adding water to the reaction product is carried out, so as to obtain the desired novolac-type phenolic hydroxy group-containing resin.

In view of excellent balance among developability, heat resistance, and dry etching resistance and suitability as a resist material, the weight average molecular weight (Mw) of the novolac-type phenolic hydroxy group-containing resin obtained as described above is preferably 1,500 to 30,000. In addition, the polydispersity (Mw/Mn) of the novolac-type phenolic hydroxy group-containing resin is preferably 1 to 10.

The weight average molecular weight (Mw) and polydispersity (Mw/Mn) in the present invention are values measured by GPC under the same conditions as the conditions for the calculation of the purity of the tetrafunctional phenol compound (A).

In view of excellent balance among developability, heat resistance, and dry etching resistance and suitability as a resist material, it is preferable that the novolac-type phenolic hydroxy group-containing resin of the present invention includes a dimer in which the number of the repeating units with respect to the total of the structural moiety (I) represented by Structural Formula (1) and the structural moiety (II) represented by Structural Formula (2) is two, or a trimer in which the number of the repeating units with respect to the total of the structural moiety (I) represented by Structural Formula (1) and the structural moiety (II) represented by Structural Formula (2) is three.

Examples of the dimer include a dimer having a molecular structure represented by any one of Structural Formulas (II-1) to (II-3).

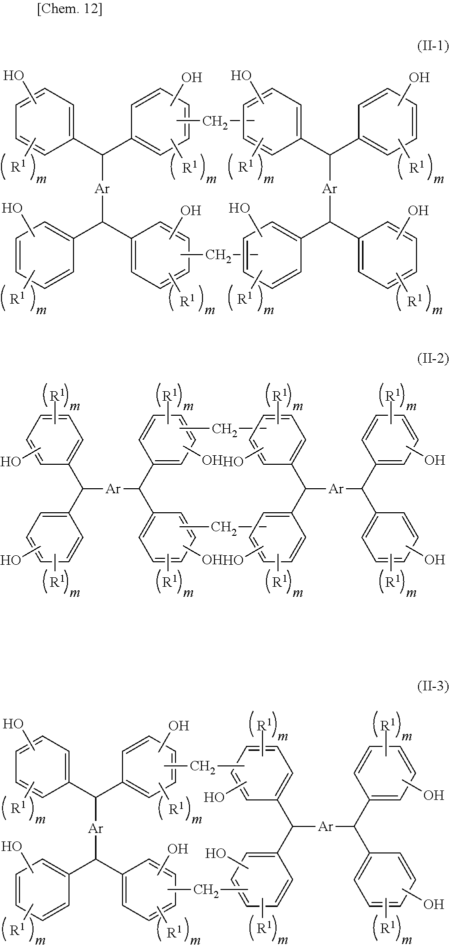

(In the formula, Ar represents an arylene group, R¹'s each independently represent any one of a hydrogen atom, an alkyl group, an alkoxy group, an aryl group, an aralkyl group, and a halogen atom, and m's each independently represent an integer of 1 to 3.)

Examples of the trimer include a trimer having a molecular structure represented by any one of Structural Formulas (III-1) to (III-6).

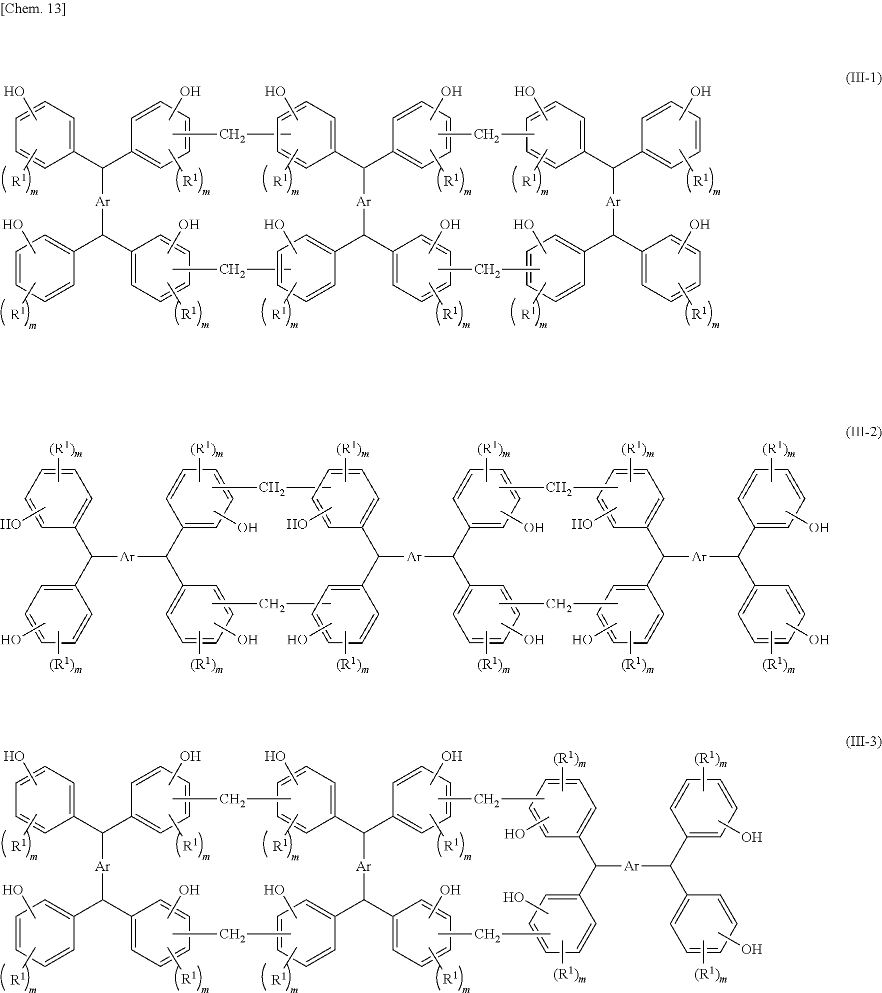

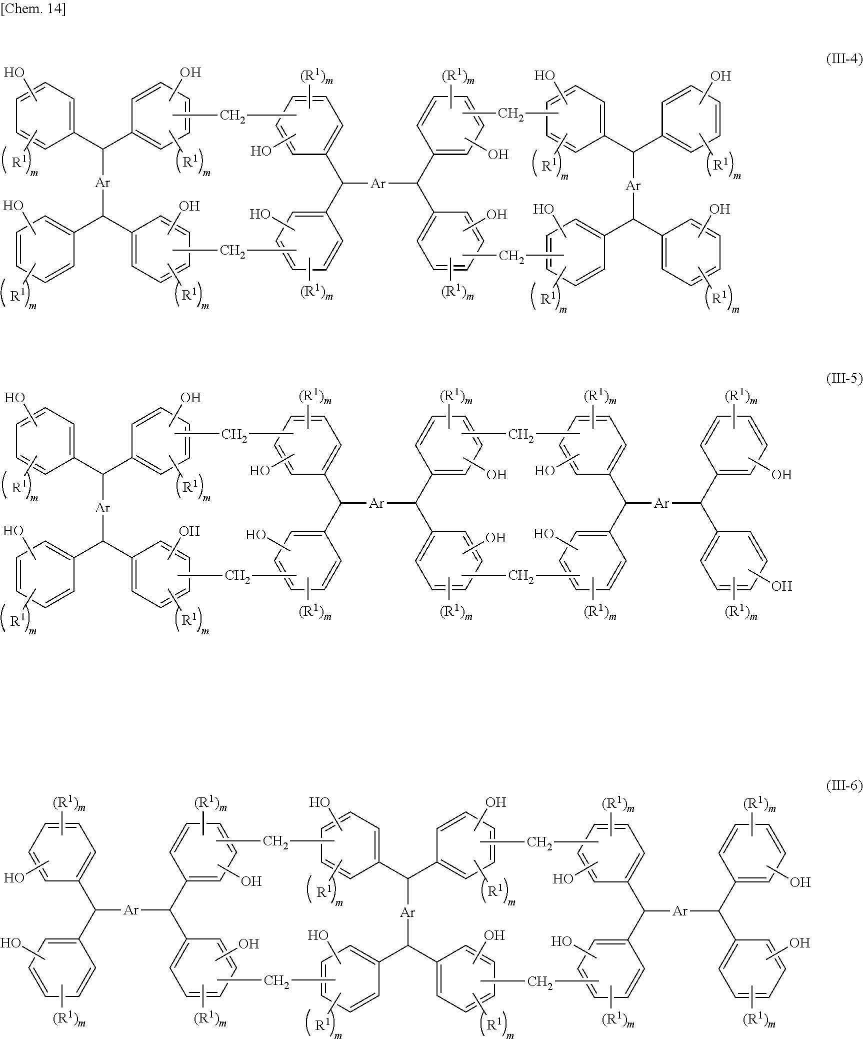

(In the formula, Ar represents an arylene group, R¹'s each independently represent any one of a hydrogen atom, an alkyl group, an alkoxy group, an aryl group, an aralkyl group, and a halogen atom, and m's each independently represent an integer of 1 to 3.)

In the case where the novolac-type phenolic hydroxy group-containing resin includes the dimer, the content of the dimer is preferably 5% to 90%, in view of obtaining the novolac-type phenolic hydroxy group-containing resin having particularly excellent developability. In the case where the novolac-type phenolic hydroxy group-containing resin includes the trimer, the content of the trimer is preferably 5% to 90%, in view of obtaining the novolac-type phenolic hydroxy group-containing resin having excellent heat resistance. The content of the dimer or the trimer in the novolac-type phenolic hydroxy group-containing resin is a value calculated from the area ratio of the GPC chart diagram measured under the same conditions as the conditions for the calculation of the purity of the tetrafunctional phenol compound (A).

In view of excellent solubility in a general-purpose organic solvent and heat resistance, the novolac-type phenolic hydroxy group-containing resin of the present invention described in detail so far can be used for various electrical and electronic members such as an adhesive or paint, a photoresist, and a printed wiring board. Among these uses, the novolac-type phenolic hydroxy group-containing resin is particularly suitably used for a resist that makes use of the characteristics of excellent developability, heat resistance, and dry etching resistance of the resin. The novolac-type phenolic hydroxy group-containing resin can be preferably used as a resist material having alkali developability by being combined with a photosensitizing agent, or can be used for a thick film, a resist underlayer film, or a resist permanent film by being combined with a curing agent.

A photosensitive composition of the present invention includes the novolac-type phenolic hydroxy group-containing resin of the present invention and a photosensitizing agent as essential components. In the photosensitive composition of the present invention, a resin (X) other than the novolac-type phenolic hydroxy group-containing resin of the present invention may be used together with the above components. As the other resin (X), any resin can be used as long as the resin is soluble in an alkali developer or can be dissolved in an alkali developer by being used in combination with an additive such as an acid generator.

Examples of the other resin (X) used here include a phenol resin (X-1) other than the phenolic hydroxy group-containing resin, a homopolymer or a copolymer (X-2) of a hydroxy group-containing styrene compound such as p-hydroxystyrene and p-(1,1,1,3,3,3-hexafluoro-2-hydroxypropyl)styrene, a resin (X-3) obtained by modifying a hydroxy group of (X-1) or (X-2) with an acid decomposable group such as a t-butoxycarbonyl group and a benzyloxycarbonyl group, a homopolymer or a copolymer (X-4) of (meth)acrylic acid, an alternating polymer (X-5) of an alicyclic polymerizable monomer such as a norbornene compound and a tetracyclododecene compound and maleic anhydride or maleimide, and the like.

Examples of the other phenol resin (X-1) include phenol resins such as a phenol novolac resin, a cresol novolac resin, a naphthol novolac resin, a co-condensed novolac resin obtained by using various phenolic compounds, an aromatic hydrocarbon formaldehyde resin-modified phenol resin, a dicyclopentadiene phenol adduct resin, a phenol aralkyl resin (XYLOK resin), a naphthol aralkyl resin, a trimethylolmethane resin, a tetraphenylolethane resin, a biphenyl-modified phenol resin (a polyhydric phenol compound in which phenol nuclei are linked by a bismethylene group), a biphenyl-modified naphthol resin (a polyhydric naphthol compound in which phenol nuclei are linked by a bismethylene group), an aminotriazine-modified phenol resin (a polyhydric phenol compound in which phenol nuclei are linked by melamine, benzoguanamine, or the like), and an alkoxy group-containing aromatic ring-modified novolac resin (a polyhydric phenol compound in which a phenol nucleus is linked with an alkoxy group-containing aromatic ring by formaldehyde).

Among the other phenol resins (X), in view of obtaining a photosensitive resin composition having high sensitivity and excellent heat resistance, a cresol novolac resin or a co-condensed novolac resin of cresol and another phenolic compound is preferable. The cresol novolac resin or the co-condensed novolac resin of cresol and another phenolic compound is specifically a novolac resin obtained by using at least one cresol selected from the group consisting of o-cresol, m-cresol, and p-cresol and an aldehyde compound as essential raw materials and using the essential raw materials in combination with another suitable phenolic compound.

Examples of the other phenolic compound besides the cresol include phenol; xylenol such as 2,3-xylenol, 2,4-xylenol, 2,5-xylenol, 2,6-xylenol, 3,4-xylenol, and 3,5-xylenol; ethylphenol such as o-ethylphenol, m-ethylphenol, and p-ethylphenol; butylphenol such as isopropylphenol, butylphenol, and p-t-butylphenol; alkylphenol such as p-pentylphenol, p-octylphenol, p-nonylphenol, and p-cumylphenol; halogenated phenol such as fluorophenol, chlorophenol, bromophenol, and iodophenol; monosubstituted phenol such as p-phenylphenol, aminophenol, nitrophenol, dinitrophenol, and trinitrophenol; fused polycyclic phenol such as 1-naphthol and 2-naphthol; and polyhydric phenol such as resorcin, alkyl resorcin, pyrogallol, catechol, alkyl catechol, hydroquinone, alkyl hydroquinone, phloroglucin, bisphenol A, bisphenol F, bisphenol S, and dihydroxynaphthalene. These other phenolic compounds may be used singly, or two or more kinds thereof may be used in combination. In the case where these other phenolic compounds are used, the amount of the compounds used is preferably set such that the number of moles of the other phenolic compounds is 0.05 to 1 mol with respect to the total of 1 mol of the cresol raw material.

Furthermore, examples of the aldehyde compound include formaldehyde, paraformaldehyde, trioxane, acetaldehyde, propionaldehyde, polyoxymethylene, chloral, hexamethylenetetramine, furfural, glyoxal, n-butyl aldehyde, caproaldehyde, allyl aldehyde, benzaldehyde, crotonaldehyde, acrolein, tetraoxymethylene, phenylacetaldehyde, o-tolualdehyde, and salicylaldehyde, and each of these aldehyde compounds may be used singly, or two or more kinds thereof may be used in combination. Among these, in view of excellent reactivity, formaldehyde is preferable, and formaldehyde may be used in combination with another aldehyde compound. In the case where formaldehyde is used in combination with another aldehyde compound, the amount of another aldehyde compound used is preferably 0.05 to 1 mol with respect to 1 mol of formaldehyde.

In view of obtaining the photosensitive resin composition having excellent sensitivity and heat resistance, the reaction ratio between the phenolic compound and the aldehyde compound when producing a novolac resin is set such that the number of moles of the aldehyde compound is preferably 0.3 to 1.6 mol and more preferably 0.5 to 1.3 with respect to 1 mol of the phenolic compound.

Examples of the method for the reaction between the phenolic compound and the aldehyde compound include a method in which the reaction is carried out under the temperature condition of 60° C. to 140° C. in the presence of an acid catalyst and then water and residual monomers are removed under the condition of a reduced pressure. Examples of the acid catalyst used here include oxalic acid, sulfuric acid, hydrochloric acid, phenolsulfonic acid, p-toluenesulfonic acid, zinc acetate, and manganese acetate, and each of these acid catalysts may be used singly, or two or more kinds thereof may be used in combination. Among these, from the viewpoint of excellent catalytic activity, oxalic acid is preferable.

Among the cresol novolac resin or the co-condensed novolac resin of cresol and another phenolic compound described above in detail, a cresol novolac resin obtained by solely using m-cresol or a cresol novolac resin obtained by using m-cresol and p-cresol together is preferable. In the latter case, the reaction molar ratio between m-cresol and p-cresol [m-cresol/p-cresol] is preferably 10/0 to 2/8 and more preferably 7/3 to 2/8, in view of obtaining the photosensitive resin composition having excellent balance between sensitivity and heat resistance.

In the case where the other resin (X) is used, the blending ratio between the novolac-type phenolic hydroxy group-containing resin of the present invention and the other resin (X) can be arbitrarily adjusted according to the desired use. For example, since optical sensitivity, resolution, and heat resistance of the novolac-type phenolic hydroxy group-containing resin of the present invention are excellent when the resin is used in combination with the photosensitizing agent, the photosensitive composition including the novolac-type phenolic hydroxy group-containing resin of the present invention and the photosensitizing agent as the main components is optimal for use in a resist. Here, in view of obtaining a curable composition having high optical sensitivity and excellent resolution and heat resistance, the proportion of the novolac-type phenolic hydroxy group-containing resin of the present invention in the total resin components is preferably 60% by mass or higher and more preferably 80% by mass or higher.

The novolac-type phenolic hydroxy group-containing resin of the present invention can be used as a sensitivity improving agent by making use of the characteristic of excellent optical sensitivity of the resin. In this case, the blending ratio between the novolac-type phenolic hydroxy group-containing resin of the present invention and the other resin (X) is preferably set such that the amount of the novolac-type phenolic hydroxy group-containing resin of the present invention is 3 to 80 parts by mass with respect to 100 parts by mass of the other resin (X).

Examples of the photosensitizing agent include a compound having a quinone diazide group. Specific examples of the compound having a quinone diazide group include a complete ester compound, a partial ester compound, an amidated product, or a partial amidated product of an aromatic (poly)hydroxy compound and sulfonic acid having a quinone diazide group such as naphthoquinone-1,2-diazide-5-sulfonic acid, naphthoquinone-1,2-diazide-4-sulfonic acid, and ortho-anthraquinone diazide sulfonic acid.

Examples of the aromatic (poly)hydroxy compound used here include a polyhydroxybenzophenone compound such as 2,3,4-trihydroxybenzophenone, 2,4,4′-trihydroxybenzophenone, 2,4,6-trihydroxybenzophenone, 2,3,6-trihydroxybenzophenone, 2,3,4-trihydroxy-2′-methylbenzophenone, 2,3,4,4′-tetrahydroxybenzophenone, 2,2′,4,4′-tetrahydroxybenzophenone, 2,3′,4,4′,6-pentahydroxybenzophenone, 2,2′,3,4,4′-pentahydroxybenzophenone, 2,2′,3,4,5-pentahydroxybenzophenone, 2,3′,4,4′,5′,6-hexahydroxybenzophenone, and 2,3,3′,4,4′,5′-hexahydroxybenzophenone;

a bis[(poly)hydroxyphenyl]alkane compound such as bis(2,4-dihydroxyphenyl)methane, bis(2,3,4-trihydroxyphenyl)methane, 2-(4-hydroxyphenyl)-2-(4′-hydroxyphenyl)propane, 2-(2,4-dihydroxyphenyl)-2-(2′,4′-dihydroxyphenyl)propane, 2-(2,3,4-trihydroxyphenyl)-2-(2′,3′,4′-trihydroxyphenyl)propane, 4,4′-{1-[4-[2-(4-hydroxyphenyl)-2-propyl]phenyl]ethylidene }bisphenol, and 3,3′-dimethyl-{1-[4-[2-(3-methyl-4-hydroxyphenyl)-2-propyl ]phenyl]ethylidene}bisphenol;

a tris(hydroxyphenyl)methane compound such as tris(4-hydroxyphenyl)methane, bis(4-hydroxy-3,5-dimethylphenyl)-4-hydroxyphenylmethane, bis(4-hydroxy-2,5-dimethylphenyl)-4-hydroxyphenylmethane, bis(4-hydroxy-3,5-dimethylphenyl)-2-hydroxyphenylmethane, bis(4-hydroxy-2,5-dimethylphenyl)-2-hydroxyphenylmethane, bis(4-hydroxy-2,5-dimethylphenyl)-3,4-dihydroxyphenylmetha ne, and bis(4-hydroxy-3,5-dimethylphenyl)-3,4-dihydroxyphenylmetha ne or a methyl substitution product thereof;

and a bis(cyclohexylhydroxyphenyl)(hydroxyphenyl)methane compound such as bis(3-cyclohexyl-4-hydroxyphenyl)-3-hydroxyphenylmethane, bis(3-cyclohexyl-4-hydroxyphenyl)-2-hydroxyphenylmethane, bis(3-cyclohexyl-4-hydroxyphenyl)-4-hydroxyphenylmethane, bis(5-cyclohexyl-4-hydroxy-2-methylphenyl)-2-hydroxyphenyl methane, bis(5-cyclohexyl-4-hydroxy-2-methylphenyl)-3-hydroxyphenyl methane, bis(5-cyclohexyl-4-hydroxy-2-methylphenyl)-4-hydroxyphenyl methane, bis(3-cyclohexyl-2-hydroxyphenyl)-3-hydroxyphenylmethane, bis(5-cyclohexyl-4-hydroxy-3-methylphenyl)-4-hydroxyphenyl methane, bis(5-cyclohexyl-4-hydroxy-3-methylphenyl)-3-hydroxyphenyl methane, bis(5-cyclohexyl-4-hydroxy-3-methylphenyl)-2-hydroxyphenyl methane, bis(3-cyclohexyl-2-hydroxyphenyl)-4-hydroxyphenylmethane, bis(3-cyclohexyl-2-hydroxyphenyl)-2-hydroxyphenylmethane, bis(5-cyclohexyl-2-hydroxy-4-methylphenyl)-2-hydroxyphenyl methane, and bis(5-cyclohexyl-2-hydroxy-4-methylphenyl)-4-hydroxyphenyl methane or a methyl substitution product thereof. Each of these photosensitizing agents may be used singly, or two or more kinds thereof may be used in combination.

In view of obtaining the photosensitive composition having excellent optical sensitivity, the blending amount of the photosensitizing agent in the photosensitive composition of the present invention is preferably 5 to 50 parts by mass with respect to the total of 100 parts by mass of the resin solid contents in the photosensitive composition.

The photosensitive composition of the present invention may include a surfactant for the purpose of improving film forming properties in the case of using the composition for a resist and adhesiveness of a pattern and reducing development defects. Examples of the surfactant used here include a nonionic surfactant such as a polyoxyethylene alkyl ether compound such as polyoxyethylene lauryl ether, polyoxyethylene stearyl ether, polyoxyethylene cetyl ether, and polyoxyethylene oleyl ether, a polyoxyethylene alkyl allyl ether compound such as polyoxyethylene octylphenol ether, and polyoxyethylene nonylphenol ether, a sorbitan fatty acid ester compound such as polyoxyethylene-polyoxypropylene block copolymer, sorbitan monolaurate, sorbitan monopalmitate, sorbitan monostearate, sorbitan monooleate, sorbitan trioleate, and sorbitan tristearate, and a polyoxyethylene sorbitan fatty acid ester compound such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; a fluorine-based surfactant having a fluorine atom in the molecular structure thereof such as a copolymer of a polymerizable monomer having a fluoroaliphatic group and [poly(oxyalkylene)](meth)acrylate; and a silicone-based surfactant having a silicone structural moiety in the molecular structure thereof. These surfactants may be used singly, or two or more kinds thereof may be used in combination.

The blending amount of these surfactants is preferably 0.001 to 2 parts by mass with respect to the total of 100 parts by mass of the resin solid contents in the photosensitive composition of the present invention.

In the case where the photosensitive composition of the present invention is used for a photoresist, the composition can be used as a composition for a resist by adding, as necessary, the other phenol resin (X) and various additives such as a surfactant, a dye, a filler, a crosslinking agent, and a dissolution promotor, in addition to the novolac-type phenolic hydroxy group-containing resin of the present invention and the photosensitizing agent, and dissolving the above components in an organic solvent. This may be used as a positive tone resist solution as it is, or the composition for a resist may be used as a positive tone resist film by applying the composition in a film shape and removing the solvent. Examples of a support film when used as the resist film include a synthetic resin film such as polyethylene, polypropylene, polycarbonate, and polyethylene terephthalate, and the film may be used as a single layer film or a plurality of multilayer films. The surface of the support film may be subjected to a corona treatment or may be coated with a release agent.

The organic solvent used for the composition for a resist of the present invention is not particularly limited, and examples thereof include alkylene glycol monoalkyl ether such as ethylene glycol monomethyl ether, ethylene glycol monoethyl ether, ethylene glycol monopropyl ether, ethylene glycol monobutyl ether, and propylene glycol monomethyl ether; dialkylene glycol dialkyl ether such as diethylene glycol dimethyl ether, diethylene glycol diethyl ether, diethylene glycol dipropyl ether, and diethylene glycol dibutyl ether; alkylene glycol alkyl ether acetate such as ethylene glycol monomethyl ether acetate, ethylene glycol monoethyl ether acetate, and propylene glycol monomethyl ether acetate; a ketone compound such as acetone, methyl ethyl ketone, cyclohexanone, and methyl amyl ketone; a cyclic ether such as dioxane; and an ester compound such as methyl 2-hydroxypropionate, ethyl 2-hydroxypropionate, ethyl 2-hydroxy-2-methylpropionate, ethyl ethoxyacetate, ethyl oxyacetate, methyl 2-hydroxy-3-methylbutanoate, 3-methoxybutyl acetate, 3-methyl-3-methoxybutyl acetate, ethyl formate, ethyl acetate, butyl acetate, methyl acetoacetate, and ethyl acetoacetate. Each of these organic solvents may be used singly, or two or more kinds thereof may be used in combination.

The composition for a resist of the present invention can be prepared by blending each of the components and performing mixing using a stirrer. In the case where a resin composition for a photoresist includes a filler or a pigment, the composition can be prepared by dispersing or mixing the components using a dispersing device such as a dissolver, a homogenizer, and a three roll mill.

In a photolithography method using the composition for a resist of the present invention, for example, an object to be subjected to photolithography such as a silicon substrate is coated with the composition for a resist, and prebaking is performed under a temperature condition of 60° C. to 150° C. A coating method used here may be any method such as spin coating, roll coating, flow coating, dip coating, spray coating, and doctor blade coating. Next, a resist pattern is created, however, since the composition for a resist of the present invention is a positive-tone resist composition, a resist pattern is formed by exposing a desired resist pattern through a prescribed mask and dissolving the exposed portion with an alkali developer. In the composition for a resist of the present invention, both alkali solubility of the exposed portion and alkali insolubility of the unexposed portion are high, and thus, it is possible to form a resist pattern with excellent resolution.

The curable composition of the present invention includes the novolac-type phenolic hydroxy group-containing resin of the present invention and a curing agent as essential components. In the curable composition of the present invention, a resin (Y) other than the novolac-type phenolic hydroxy group-containing resin of the present invention may be used together with the above components. Examples of the other resin (Y) used here include various novolac resins, a resin formed by addition polymerization of an alicyclic diene compound such as dicyclopentadiene and a phenol compound, a modified novolac resin of a phenolic hydroxy group-containing compound and an alkoxy group-containing aromatic compound, a phenol aralkyl resin (XYLOK resin), a naphthol aralkyl resin, a trimethylolmethane resin, a tetraphenylolethane resin, a biphenyl-modified phenol resin, a biphenyl-modified naphthol resin, an aminotriazine-modified phenol resin, and various vinyl polymers.

More specifically, examples of the various novolac resins include a polymer obtained by reacting a phenolic hydroxy group-containing compound, for example, phenol, an alkylphenol such as cresol and xylenol, a phenylphenol, resorcinol, biphenyl, bisphenol such as bisphenol A and bisphenol F, naphthol, dihydroxynaphthalene, or the like, with an aldehyde compound, under the condition of an acid catalyst.

Examples of the various vinyl polymer include a homopolymer or a copolymer of vinyl compounds such as polyhydroxystyrene, polystyrene, polyvinyl naphthalene, polyvinyl anthracene, polyvinyl carbazole, polyindene, polyacenaphthylene, polynorbornene, polycyclodecene, polytetracyclododecene, polynortricyclene, and poly(meth)acrylate.

In the case where these other resins are used, the blending ratio between the novolac-type phenolic hydroxy group-containing resin of the present invention and the other resin (Y) can be arbitrarily set according to the use, however, in view of more remarkably expressing the effect of excellent dry etching resistance and resistance to thermal decomposition exhibited by the present invention, the blending ratio is preferably set such that the amount of the other resin (Y) is 0.5 to 100 parts by mass with respect to 100 parts by mass of the novolac-type phenolic hydroxy group-containing resin of the present invention.

Examples of the curing agent used in the present invention include a melamine compound substituted with at least one group selected from the group consisting of a methylol group, an alkoxymethyl group, and an acyloxymethyl group, a guanamine compound, a glycoluril compound, a urea compound, a resole resin, an epoxy compound, an isocyanate compound, an azide compound, a compound containing a double bond such as an alkenyl ether group, an acid anhydride, and an oxazoline compound.

Examples of the melamine compound include hexamethylol melamine, hexamethoxymethyl melamine, a compound in which one to six methylol groups of hexamethylol melamine are methoxy methylated, hexamethoxyethyl melamine, hexaacyloxymethyl melamine, and a compound in which one to six methylol groups of hexamethylol melamine are acyloxymethylated.

Examples of the guanamine compound include tetramethylol guanamine, tetramethoxymethyl guanamine, tetramethoxymethyl benzoguanamine, a compound in which one to four methylol groups of tetramethylol guanamine are methoxy methylated, tetramethoxyethyl guanamine, tetraacyloxy guanamine, and a compound in which one to four methylol groups of tetramethylol guanamine are acyloxymethylated.

Examples of the glycoluril compound include 1,3,4,6-tetrakis(methoxymethyl)glycoluril, 1,3,4,6-tetrakis(butoxymethyl)glycoluril, and 1,3,4,6-tetrakis(hydroxymethyl)glycoluril.

Examples of the urea compound include 1,3-bis(hydroxymethyl)urea, 1,1,3,3-tetrakis(butoxymethyl)urea, and 1,1,3,3-tetrakis(methoxymethyl)urea.

Examples of the resol resin include a polymer obtained by reacting a phenolic hydroxy group-containing compound, for example, phenol, alkylphenol such as cresol and xylenol, phenylphenol, resorcinol, biphenyl, bisphenol such as bisphenol A and bisphenol F, naphthol, and dihydroxynaphthalene with an aldehyde compound under the condition of an alkali catalyst.

Examples of the epoxy compound include diglycidyloxynaphthalene, a phenol novolac-type epoxy resin, a cresol novolac-type epoxy resin, a naphthol novolac-type epoxy resin, a naphthol-phenol co-condensed novolac-type epoxy resin, a naphthol-cresol co-condensed novolac-type epoxy resin, a phenol aralkyl-type epoxy resin, a naphthol aralkyl-type epoxy resin, 1,1-bis(2, 7-diglycidyloxy-1-naphthyl)alkane, a naphthylene ether-type epoxy resin, a triphenyl methane-type epoxy resin, a dicyclopentadiene-phenol addition reaction-type epoxy resin, a phosphorus atom-containing epoxy resin, and a polyglycidyl ether of a co-condensate of a phenolic hydroxy group-containing compound and an alkoxy group-containing aromatic compound.

Examples of the isocyanate compound include tolylene diisocyanate, diphenylmethane diisocyanate, hexamethylene diisocyanate, and cyclohexane diisocyanate.

Examples of the azide compound include 1,1′-biphenyl-4,4′-bis azide, 4,4′-methylidene bis azide, and 4,4′-oxy bis azide.

Examples of the compound containing a double bond such as an alkenyl ether group include ethylene glycol divinyl ether, triethylene glycol divinyl ether, 1,2-propanediol divinyl ether, 1,4-butanediol divinyl ether, tetramethylene glycol divinyl ether, neopentyl glycol divinyl ether, trimethylol propane trivinyl ether, hexanediol divinyl ether, 1,4-cyclohexanediol divinyl ether, pentaerythritol trivinyl ether, pentaerythritol tetravinyl ether, sorbitol tetravinyl ether, sorbitol pentavinyl ether, and trimethylol propane trivinyl ether.

Examples of the acid anhydride include an aromatic acid anhydride such as phthalic anhydride, trimellitic anhydride, pyromellitic anhydride, 3,3′,4,4′-benzophenonetetracarboxylic dianhydride, biphenyltetracarboxylic dianhydride, 4,4′-(isopropylidene)diphthalic anhydride, and 4,4′-(hexafluoroisopropylidene)diphthalic anhydride; and an alicyclic carboxylic anhydride such as tetrahydrophthalic anhydride, methyltetrahydrophthalic anhydride, hexahydrophthalic anhydride, methylhexahydrophthalic anhydride, endomethylenetetrahydrophthalic anhydride, dodecenylsuccinic anhydride, and trialkyltetrahydrophthalic anhydride.

Among these, in view of obtaining the curable composition having excellent curability and heat resistance in the cured product, a glycoluril compound, a urea compound, and a resol resin are preferable, and a glycoluril compound is particularly preferable.

In view of obtaining the composition having excellent curability, the blending amount of the curing agent in the curable composition of the present invention is preferably 0.5 to 50 parts by mass with respect to the total of 100 parts by mass of the novolac-type phenolic hydroxy group-containing resin of the present invention and the other resin (Y).

In the case where the curable composition of the present invention is used for a resist underlayer film (BARC film), the composition can be used as a composition for a resist underlayer film by adding, as necessary, the other resin (Y), and various additives such as a surfactant, a dye, a filler, a crosslinking agent, and a dissolution promotor, in addition to the novolac-type phenolic hydroxy group-containing resin of the present invention and the curing agent, and dissolving the above components in an organic solvent.

The organic solvent used for the composition for a resist underlayer film is not particularly limited, and examples thereof include alkylene glycol monoalkyl ether such as ethylene glycol monomethyl ether, ethylene glycol monoethyl ether, ethylene glycol monopropyl ether, ethylene glycol monobutyl ether, and propylene glycol monomethyl ether; dialkylene glycol dialkyl ether such as diethylene glycol dimethyl ether, diethylene glycol diethyl ether, diethylene glycol dipropyl ether, and diethylene glycol dibutyl ether; alkylene glycol alkyl ether acetate such as ethylene glycol monomethyl ether acetate, ethylene glycol monoethyl ether acetate, and propylene glycol monomethyl ether acetate; a ketone compound such as acetone, methyl ethyl ketone, cyclohexanone, and methyl amyl ketone; a cyclic ether such as dioxane; and an ester compound such as methyl 2-hydroxypropionate, ethyl 2-hydroxypropionate, ethyl 2-hydroxy-2-methylpropionate, ethyl ethoxyacetate, ethyl oxyacetate, methyl 2-hydroxy-3-methylbutanoate, 3-methoxybutyl acetate, 3-methyl-3-methoxybutyl acetate, ethyl formate, ethyl acetate, butyl acetate, methyl acetoacetate, and ethyl acetoacetate. Each of these organic solvents may be used singly, or two or more kinds thereof may be used in combination.

The composition for a resist underlayer film can be prepared by blending each of the components and performing mixing using a stirrer. In the case where the composition for a resist underlayer film includes a filler or a pigment, the composition can be prepared by dispersing or mixing the components using a dispersing device such as a dissolver, a homogenizer, and a three roll mill.

In the case where the resist underlayer film is prepared from the composition for a resist underlayer film, the resist underlayer film is formed by a method in which an object to be subjected to photolithography such as a silicon substrate is coated with the composition for a resist underlayer film, and the composition is dried under the temperature condition of 100° C. to 200° C., and then thermally cured under the temperature condition of 250° C. to 400° C. Next, a resist pattern can be formed using a multilayer resist method by performing a conventional photolithography operation on the underlayer film so as to forma resist pattern and performing a dry etching treatment using a halogen-based plasma gas or the like.

In the case where the curable composition of the present invention is used for a resist permanent film, the composition can be used as a composition for a resist permanent film by adding, as necessary, the other phenol resin (Y) and various additives such as a surfactant, a dye, a filler, a crosslinking agent, and a dissolution promotor, in addition to the novolac-type phenolic hydroxy group-containing resin of the present invention and the curing agent and dissolving the above components in an organic solvent. Examples of the organic solvent used here are the same as the examples of the organic solvents used for the composition for a resist underlayer film.

In a photolithography method using the composition for a resist permanent film, for example, the resin component and the additive components are dissolved and dispersed in the organic solvent and then applied onto an object to be subjected to photolithography such as a silicon substrate, and prebaking is performed under a temperature condition of 60° C. to 150° C. A coating method used here may be any method such as spin coating, roll coating, flow coating, dip coating, spray coating, and doctor blade coating. Next, a resist pattern is created, however, in the case where the composition for a resist permanent film is a positive-tone composition, a resist pattern is formed by exposing a desired resist pattern through a prescribed mask and dissolving the exposed portion with an alkali developer.

In the case of a semiconductor device, a permanent film formed of the composition for a resist permanent film can be suitably used in a packaging adhesive layer between a solder resist, a packaging material, an underfill material, and a circuit element, or an adhesive layer between an integrated circuit element and a circuit substrate, and in the case of a thin display represented by LCD and OELD, the permanent film formed of the composition for a resist permanent film can be suitably used in a thin film transistor protective film, a liquid crystal color filter protective film, a black matrix, or a spacer.

### Examples

The present invention will be described in more detail using the following specific examples. The number average molecular weight (Mn), the weight average molecular weight (Mw), and the polydispersity (Mw/Mn) of a synthesized resin were measured by GPC under the following measurement condition, and the purity and the contents of a dimer and a trimer were calculated from the area ratio of the GPC chart diagram obtained under the following measurement condition.

### [Measurement Condition for GPC]

Measurement device: “HLC-8220 GPC” manufactured by Tosoh Corporation

Column: “Shodex KF802” (8.0 mmϕ×300 mm) manufactured by Showa Denko K.K.+“ShodexKF802” (8.0 mmϕ×300 mm) manufactured by Showa Denko K.K.

+“Shodex KF803” (8.0 mmϕ×300 mm) manufactured by Showa Denko K.K. +“Shodex KF804” (8.0 mmϕ×300 mm) manufactured by Showa Denko K.K.

Column temperature: 40° C.

Detector: RI (differential refractometer)

Data processing: “GPC-8020 MODEL II VERSION 4.30” manufactured by Tosoh Corporation

Eluent: tetrahydrofuran

Flow rate: 1.0 mL/min

Sample: a sample obtained by filtering 0.5% by mass (in terms of a resin solid content) of tetrahydrofuran solution through a microfilter

Injection volume: 0.1 mL

Standard sample: the following monodisperse polystyrene

(Standard sample: monodisperse polystyrene)

“A-500” manufactured by Tosoh Corporation

“A-2500” manufactured by Tosoh Corporation

“A-5000” manufactured by Tosoh Corporation

“F-1” manufactured by Tosoh Corporation

“F-2” manufactured by Tosoh Corporation

“F-4” manufactured by Tosoh Corporation

“F-10” manufactured by Tosoh Corporation

“F-20” manufactured by Tosoh Corporation

In measurement of the ¹H-NMR spectrum, a DMSO-d₆ solution of the sample was analyzed using “AL-400” manufactured by JEOL Ltd., so as to perform structural analysis. The measurement condition for the ¹H-NMR spectrum is shown below.

### [Measurement Condition for ¹H-NMR Spectrum]

Measurement mode: SGNNE (1H complete decoupling method of NOE elimination)

Pulse angle: 45° C. pulse

Sample concentration: 30 wt %

Cumulative number: 10000 times

In measurement of the ¹³C-NMR spectrum, a DMSO-d₆ solution of the sample was analyzed using “AL-400” manufactured by JEOL Ltd., so as to perform structural analysis. The measurement condition for the ¹³C-NMR spectrum is shown below.

### [Measurement Condition for ¹³C-NMR Spectrum]

Measurement mode: SGNNE (1H complete decoupling method of NOE elimination)

Pulse angle: 45° C. pulse

Sample concentration: 30 wt %

Cumulative number: 10000 times

In measurement of the TOF-MS spectrum, the sample was analyzed using “AXIMA TOF2” manufactured by Shimadzu Corporation and using dithranol as a matrix and sodium trifluoroacetate as a cationization agent, so as to perform molecular weight analysis.

Measurement mode: linear mode

Sample adjustment: sample/dithranol/sodium trifluoroacetate/THF=10/10/1/1

### Production Example 1

### Production of Tetrafunctional Phenol Compound (A-1)

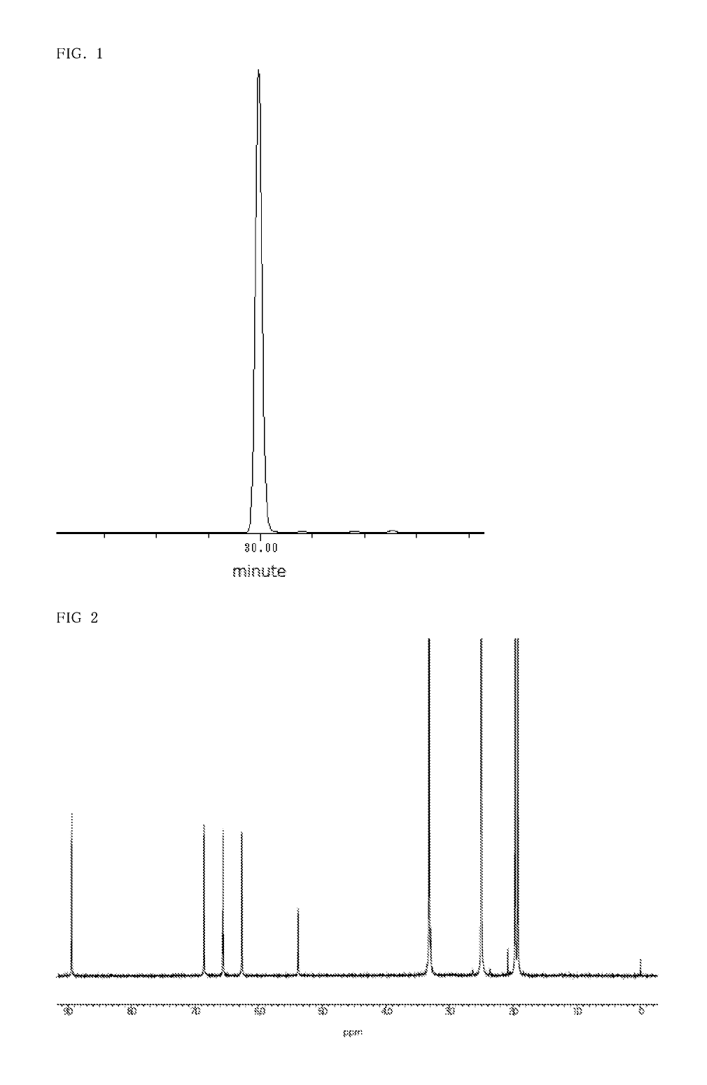

A 100 ml two-neck flask equipped with a cooling tube was charged with 73 g (0.6 mol) of 2,5-xylenol and 20 g (0.15 mol) of terephthalaldehyde, which were then dissolved in 300 ml 2-ethoxyethanol. While being cooled in an ice bath, 10 g of sulfuric acid was added thereto, and then heating and stirring were performed for 2 hours in an oil bath at 80° C. to perform a reaction. After the reaction, water was added to the obtained solution to reprecipitate a crude product. The precipitated crude product was redissolved in acetone and further reprecipitated in water. The precipitate was then isolated by filtration, and vacuum drying was performed, thereby obtaining 62 g of a pale red powder of a tetrafunctional phenol compound (A-1). The generation of a compound represented by the following structural formula was confirmed by ¹H-NMR. In addition, the purity calculated from a GPC chart diagram was 98.2%. The GPC chart of the tetrafunctional phenol compound (A-1) is shown in FIG. 1, and the ¹H-NMR chart of the compound is shown in FIG. 2.

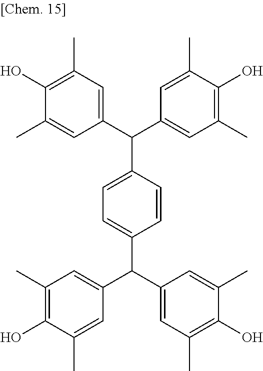

### Example 1

### Production of Novolac-Type Phenolic Hydroxy Group-Containing Resins (1) and (2)

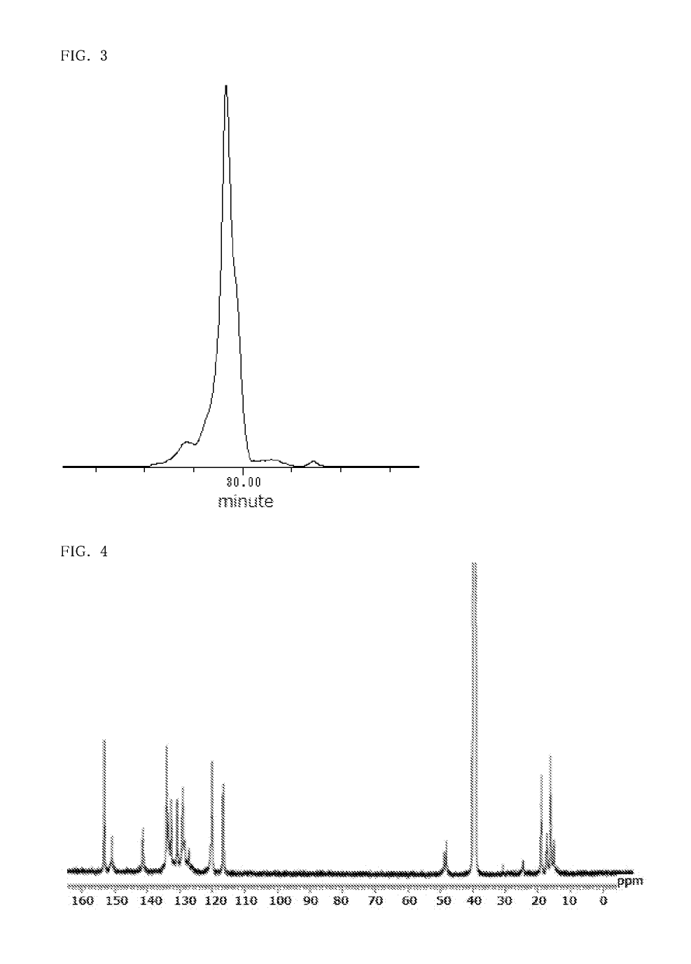

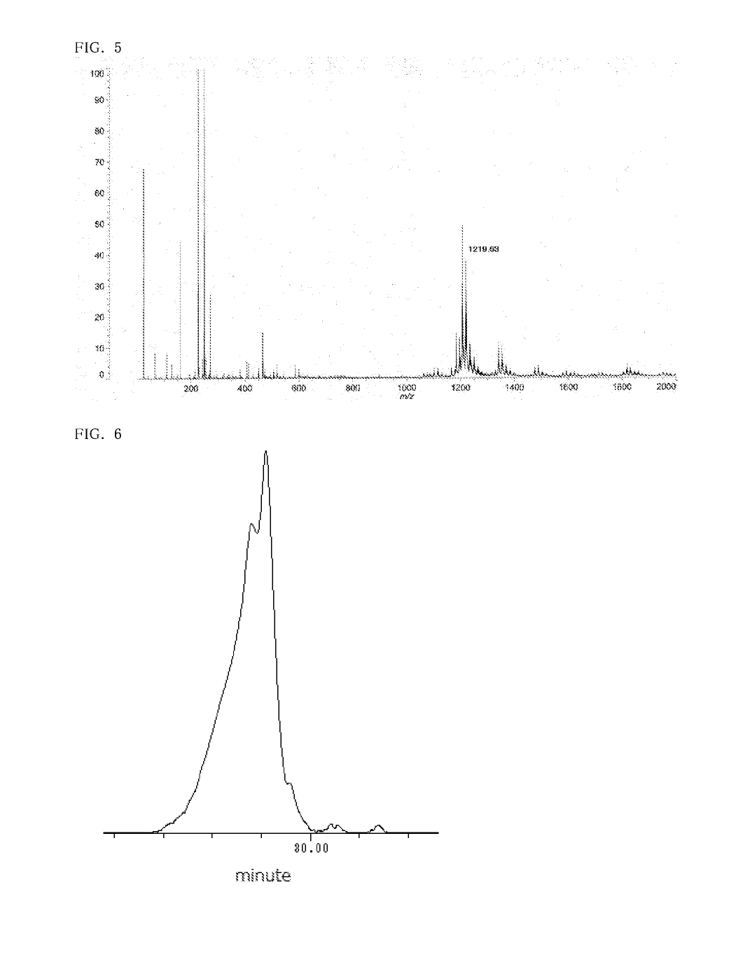

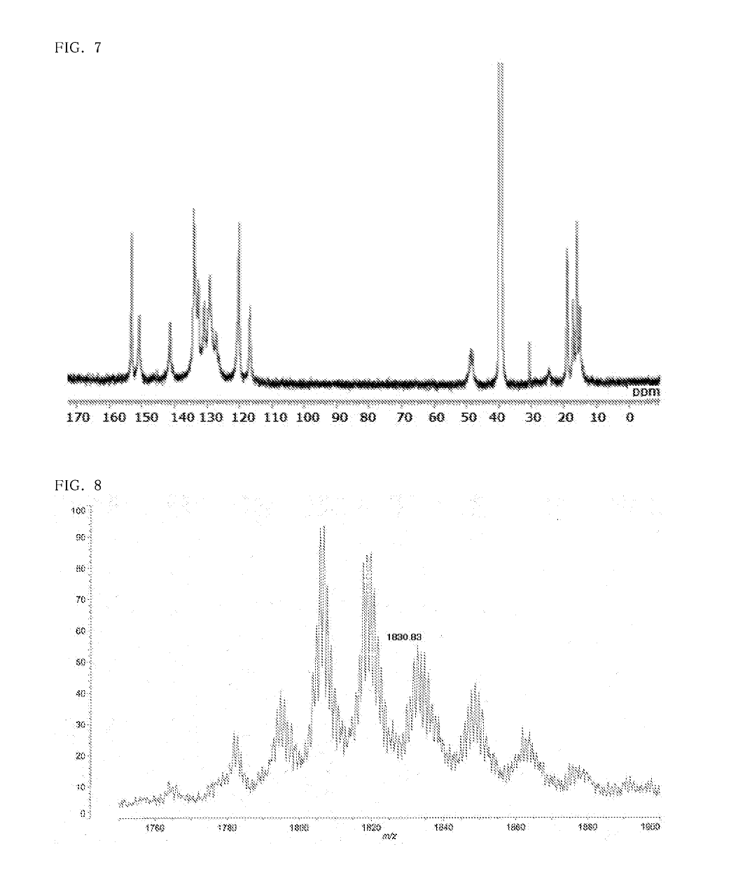

59 g (0.1 mol) of the tetrafunctional phenol compound (A-1) obtained in Production Example 1 was dissolved in a mixed solution of 250 ml of methanol and 250 ml of acetic acid in a 2 L four-neck flask equipped with a cooling tube . While being cooled in an ice bath, 20 g of sulfuric acid was added thereto, 15 g (0.5 mol) of 92% paraformaldehyde was put into the flask, and the temperature was raised to 60° C. in a water bath. Heating and stirring were continued for 10 hours to perform a reaction, and then the water was added to the obtained solution to precipitate the product. The precipitated product was isolated by filtration, and vacuum drying was performed, thereby obtaining a red solid crude product. The crude product was purified in a silica gel column (eluent: hexane/ethyl acetate=1/1), obtaining 23.4 g of a novolac-type phenolic hydroxy group-containing resin (1) including a dimer as a main component and 21.6 g of a novolac-type phenolic hydroxy group-containing resin (2) including a trimer as a main component. The GPC, 13C-NMR, and TOF-MS of the novolac-type phenolic hydroxy group-containing resin (1) are shown in FIG. 3, FIG. 4, and FIG. 5, respectively, and the GPC, 13C-NMR, and TOF-MS of the novolac-type phenolic hydroxy group-containing resin (2) are shown in FIG. 6, FIG. 7, and FIG. 8, respectively. The number average molecular weight (Mn) of the novolac-type phenolic hydroxy group-containing resin (1) was 1,552, the weight average molecular weight (Mw) was 1,666, and the polydispersity (Mw/Mn) was 1.07. A peak of 1,219 indicating the presence of a sodium adduct of the dimer was observed in the TOF-MS spectrum. The number average molecular weight (Mn) of the novolac-type phenolic hydroxy group-containing resin (2) was 2,832, the weight average molecular weight (Mw) was 3,447, and the polydispersity (Mw/Mn) was 1.22. A peak of 1,830 indicating the presence of a sodium adduct of the trimer was observed in the TOF-MS spectrum.

### Comparative Production Example 1

### Production of Novolac-Type Phenolic Hydroxy Group-Containing Resin (1′)

A 2 L four-neck flask having a stirrer and a thermometer was charged with 648 g (6 mol) of m-cresol, 432 g (4 mol) of p-cresol, 2.5 g (0.2 mol) of oxalic acid, and 492 g of 42% formaldehyde, and the temperature was raised to 100° C. to perform a reaction. Dehydration and distillation were performed under the condition of normal pressure and 200° C., and distillation under reduced pressure was performed at 230° C. for 6 hours, thereby obtaining 736 g of a pale yellow solid of a novolac-type phenolic hydroxy group-containing resin (1′). The number average molecular weight (Mn) of the novolac-type phenolic hydroxy group-containing resin (1′) was 1,450, the weight average molecular weight (Mw) was 10,316, and the polydispersity (Mw/Mn) was 7.116.

### Comparative Production Example 2

### Production of Novolac-Type Phenolic Hydroxy Group-Containing Resin (2′)

A reactor having a condenser, a thermometer, and a stirring device was charged with 100 g of 9,9-bis(4-hydroxyphenyl)fluorene, 100 g of propylene glycol monomethyl ether acetate, and 50 g of paraformaldehyde, 2 g of oxalic acid was added thereto, and the temperature was raised to 120° C. while performing dehydration. The reaction was further carried out for 5 hours, thereby obtaining 98 g of a novolac-type phenolic hydroxy group-containing resin (2′).

### Examples 2 and 3 and Comparative Examples 1 and 2

The photosensitive composition for each of the novolac-type phenolic hydroxy group-containing resins obtained in Example 1 and Comparative Production Examples 1 and 2 was prepared according to the following procedure, and various evaluations were performed. The results are shown in Table 1.

Preparation of Photosensitive Composition

7 g of the novolac-type phenolic hydroxy group-containing resin was dissolved in 15 g of propylene glycol monomethyl ether acetate, and 3 g of the photosensitizing agent was added to the solution and dissolved. This solution was filtered through a 0.2 μm membrane filter, thereby obtaining a photosensitive composition.

As the photosensitizing agent, “P-200” (a condensate of mol of 4,4′-[1-[4-[1-(4-hydroxyphenyl)-1methylethyl]phenyl]ethylidene]bisphenol and 2 mol of 1,2-naphthoquinone-2-diazide-5-sulfonyl chloride) manufactured by Toyo Gosei Co., Ltd. was used.

Preparation of Composition for Testing Heat Resistance

7 g of the phenolic hydroxy group-containing resin was dissolved in 15 g of propylene glycol monomethyl ether acetate, and this solution was filtered through a 0.2 μm membrane filter, thereby obtaining a composition for testing heat resistance.

Evaluation of Alkali Developability [ADR (nm/s)]

A 5-inch silicon wafer was coated with the photosensitive composition obtained above with a spin coater such that the thickness of the composition became approximately 1 μm, and then dried on a hot plate at 110° C. for 60 seconds. Two wafers were treated in such a way, and one was designated as a “sample without exposure”. The other one was used as an “exposed sample” and was irradiated with a ghi line at 100 mJ/cm² using a ghi line lamp (“MULTILIGHT” manufactured by USHIO INC.) and then subjected to a heating treatment at 140° C. for 60 seconds.

Both of the “sample without exposure” and the “exposed sample” were immersed in an alkali developer (2.38% tetramethylammonium hydroxide aqueous solution) for 60 seconds, and then the samples were dried on a hot plate at 110° C. for 60 seconds. Film thicknesses of each sample before and after the immersion in the developer were measured, and a value obtained by dividing the difference in the thickness by 60 was designated as alkali developability [ADR (nm/s)].

Evaluation of Optical Sensitivity

A 5-inch silicon wafer was coated with the photosensitive composition obtained above with a spin coater such that the thickness of the composition became approximately 1 μm, and then dried on a hot plate at 110° C. for 60 seconds. A mask corresponding to a resist pattern having a line/space of 1:1 and a line width being set within 1 to 10 μm in increments of 1 μm was made in close contact with the wafer, irradiation was performed with a ghi line using a ghi line lamp (“MULTILIGHT” manufactured by USHIO INC.), and a heating treatment was performed at 140° C. for 60 seconds. Next, the resultant wafer was immersed in an alkali developer (2.38% tetramethylammonium hydroxide aqueous solution) for 60 seconds and dried on a hot plate at 110° C. for 60 seconds.

In the case where the exposure amount of the ghi line was increased from 30 mJ/cm² in increments of 5 mJ/cm², an exposure amount (Eop exposure amount) at which a line width of 3 μm was able to be faithfully reproduced was evaluated.

Evaluation of Resolution

A 5-inch silicon wafer was coated with the photosensitive composition obtained above with a spin coater such that the thickness of the composition became approximately 1 μm, and then dried on a hot plate at 110° C. for 60 seconds. A photomask was placed on the obtained wafer, the wafer was irradiated with a ghi line at 200 mJ/cm², using the same method as in the case of the evaluation of alkali developability above, and then an alkali developing operation was performed. A state of a pattern was confirmed using a laser microscope (“VK-X200” manufactured by Keyence Corporation), and the case where L/S=5 μm was resolved was evaluated as A, and the case where L/S=5 μm was not resolved was evaluated as B.

Evaluation of Heat Resistance 1: Measurement of Glass Transition Temperature (Tg)

A 5-inch silicon wafer was coated with the composition for testing heat resistance obtained above with a spin coater such that the thickness of the composition became approximately 1 μm, and then dried on a hot plate at 110° C. for 60 seconds. A resin was scraped off from the obtained wafer, and a glass transition temperature (Tg) of the resin was measured. The glass transition temperature (Tg) was measured using a differential scanning calorimeter (DSC) (“Q100” manufactured by TA Instruments.) under a nitrogen atmosphere and under the condition of a temperature range of −100° C. to 300° C. and a temperature rising at a rate of 10° C./min.

Evaluation of Heat Resistance 2: Measurement of Thermal Decomposition Initiation Temperature

A 5-inch silicon wafer was coated with the composition for testing heat resistance obtained above with a spin coater such that the thickness of the composition became approximately 1 μm, and then dried on a hot plate at 110° C. for 60 seconds. A resin was scraped off from the obtained wafer, and a thermal decomposition initiation temperature was obtained by measuring weight loss when temperature was raised at a constant rate under the following condition, using a simultaneous thermogravimetric analyzer (TG/DTA).

Measuring instrument: TG/DTA 6200 manufactured by Seiko Instruments Inc.

Measurement range: RT to 400° C.

Temperature rising rate: 10° C./min

TABLE 1

| | | | | Compar- | Compar- |
|---|---|---|---|---|---|
| | | Example | Example | ative | ative |
| | | 2 | 3 | Example 1 | Example 2 |
| Novolac-type phenolic | | (1) | (2) | (1′) | (2′) |
| hydroxy group- | | | | | |
| containing resin | | | | | |
| Alkali | “Sample | 0 | 0 | 0 | 0 |
| develop- | without | | | | |
| ability | exposure” | | | | |
| ADR (nm/s) | “Exposed | >700 | 560 | 23 | 32 |
| | sample” | | | | |

| | | | | |
|---|---|---|---|---|
| Optical sensitivity | 100 | 100 | 450 | 320 |
| [mJ/cm²] | | | | |
| Resolution | A | A | B | B |
| Heat resistance [° C.] | 256 | 273 | 110 | 103 |
| Thermal decomposition | >300 | >300 | 173 | 173 |
| initiation temperature | | | | |
| [° C.] | | | | |

### Examples 4 and 5 and Comparative Examples 3 and 4

The curable composition for each of the novolac-type phenolic hydroxy group-containing resins obtained in Example 1 and Comparative Production Examples 1 and 2 was prepared according to the following procedure, and various evaluation tests were performed. The results are shown in Table 2.

Preparation of Curable Composition

4 g of the novolac-type phenolic hydroxy group-containing resin and 1 g of a curing agent (“1,3,4,6-tetrakis(methoxymethyl)glycoluril” manufactured by Tokyo Chemical Industry Co., Ltd.) were dissolved in 25 g of propylene glycol monomethyl ether acetate, and the solution was filtered through a 0.2 μm membrane filter, thereby obtaining a curable composition.

Evaluation of Alkali Developability [ADR (nm/s)]

A 5-inch silicon wafer was coated with the curable composition obtained above with a spin coater such that the thickness of the composition became approximately 1 μm, and then dried on a hot plate at 110° C. for 60 seconds. This was immersed in an alkali developer (2.38% tetramethylammonium hydroxide aqueous solution) for 60 seconds and then dried on a hot plate at 110° C. for 60 seconds. Film thicknesses before and after the immersion in the developer were measured, and a value obtained by dividing the difference in the thickness by 60 was designated as alkali developability [ADR (nm/s)].

Evaluation of Dry Etching Resistance

A 5-inch silicon wafer was coated with the curable composition obtained above with a spin coater, and then dried on a hot plate at 110° C. for 60 seconds. Heating was performed in a hot plate, in which the oxygen concentration was 20% by volume, at 180° C. for 60 seconds, and heating was further performed at 350° C. for 120 seconds, thereby obtaining a silicon wafer with a cured coating film having a film thickness of 0.3 μm. An etching treatment was performed on the cured coating film on the wafer using an etching unit (“EXAM” manufactured by Shinko Seiki Co . , Ltd.) under the condition of CF₄/Ar/O₂ (CF₄ : 40 mL/min, Ar: 20 mL/min, 0₂: 5 mL/min; pressure: 20 Pa; RF power: 200 W; treatment time: 40 seconds; temperature: 15° C.) Film thicknesses before and after the etching treatment were measured at this time, the etching rate was calculated, and the etching resistance was evaluated. The evaluation criteria are as below.

A: the case where an etching rate is 150 nm/min or lower

B: the case where an etching rate exceeds 150 nm/min

TABLE 2

| | | | Compar- | Compar- |
|---|---|---|---|---|
| | Example | Example | ative | ative |
| | 4 | 5 | Example 3 | Example 4 |
| Novolac-type phenolic | (1) | (2) | (1′) | (2′) |
| hydroxy group- | | | | |
| containing resin | | | | |
| Alkali developability | >700 | 550 | 24 | 32 |
| ADR (nm/s) | | | | |
| Dry etching resistance | A | A | B | B |

1. A novolac-type phenolic hydroxy group-containing resin comprising, as a repeating unit, a structural moiety (I) represented by Structural Formula (1): 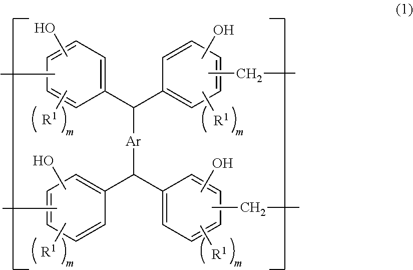
wherein Ar represents an arylene group; R¹'s each independently represent any one of a hydrogen atom, an alkyl group, an alkoxy group, an aryl group, an aralkyl group, and a halogen atom; and m's each independently represent an integer of 1 to 3,
or a structural moiety (II) represented by Structural Formula (2): 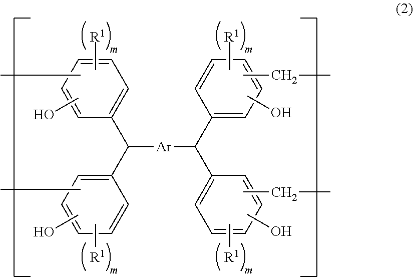
wherein Ar represents an arylene group; R¹'s each independently represent any one of a hydrogen atom, an alkyl group, an alkoxy group, an aryl group, an aralkyl group, and a halogen atom; and m's each independently represent an integer of 1 to 3.

2. The novolac-type phenolic hydroxy group-containing resin according to claim 1,
comprising a dimer in which the number of the repeating units with respect to the total of the structural moiety (I) represented by Structural Formula (1) and the structural moiety (II) represented by Structural Formula (2) is two, or a trimer in which the number of the repeating units with respect to the total of the structural moiety (I) represented by Structural Formula (1) and the structural moiety (II) represented by Structural Formula (2) is three.

3. A photosensitive composition comprising:
the novolac-type phenolic hydroxy group-containing resin according to claim 1; and
a photosensitizing agent.

4. (canceled)

5. A curable composition comprising:
the novolac-type phenolic hydroxy group-containing resin according to claim 1; and
a curing agent.

6-9. (canceled)
